(19) United States
(12) Patent Application Publication
(10) Pub. No.: US 2023/0345654 A1
(43) Pub. Date: Oct. 26, 2023

(54) DISPLAY APPARATUS AND DISPLAY MODULE

(71) Applicant: SONY GROUP CORPORATION, TOKYO (JP)

(72) Inventors: MASAMI MIIKE, KANAGAWA (JP); TAKEFUMI IKENOYA, TOKYO (JP)

(21) Appl. No.: 18/245,626

(22) PCT Filed: Sep. 30, 2021
(86) PCT No.: PCT/JP2021/036075

§ 371 Date: Mar. 16, 2023

(30) Foreign Application Priority Data
Oct. 7, 2020 (JP) 2020-169971

(51) Int. Cl. H05K 5/00; H05K 5/02

(52) U.S. Cl. CPC H05K 5/0217; H05K 5/0021

(57) ABSTRACT

A display apparatus according to an embodiment of the present technology includes at least one display module (9). The at least one display module includes a display panel (12), a support base (51), and an adjustment mechanism (52). The display panel is capable of displaying an image. The support base supports the display panel. The adjustment mechanism is connected to the display panel and connected to the support base, the adjustment mechanism being capable of adjusting a relative distance of the display panel to the support base. This makes it possible to display a high-quality image.

### TECHNICAL FIELD

The present technology relates to a display apparatus that displays an image, and a display module.

### BACKGROUND ART

Patent Literature 1 discloses a display apparatus that includes a fixture that adjusts a position of a base to which a display panel is attached. Specifically, a long side and a short side of the base are each provided with the fixture. The position of the base is adjusted by inserting an eccentric driver into the fixture and rotating the eccentric driver. This makes it possible to fix the base at a specified reference position (for example, paragraphs [0007], [0022], and [0029] to [0038] in the specification and FIG. 4 in Patent Literature 1).

### CITATION LIST

### Patent Literature

Patent Literature 1: Japanese Patent Application Laid-open No. 2015-194516

### DISCLOSURE OF INVENTION

### Technical Problem

There is a need for a technology that enables a display apparatus that can display an image to display a high-quality image.

In view of the circumstances described above, it is an object of the present technology to provide a display apparatus that can display a high-quality image, and a display module. Solution to Problem

In order to achieve the object described above, a display apparatus according to an embodiment of the present technology includes at least one display module.

The at least one display module includes a display panel, a support base, and an adjustment mechanism.

The display panel is capable of displaying an image.

The support base supports the display panel.

The adjustment mechanism is connected to the display panel and connected to the support base, the adjustment mechanism being capable of adjusting a relative distance of the display panel to the support base.

The display apparatus includes at least one display module. The display module includes an adjustment mechanism, and a relative distance of the display panel to the support base can be adjusted. This makes it possible to display a high-quality image.

The display panel may include a display surface on which the image is displayed. In this case, the adjustment mechanism may be capable of adjusting the distance in a direction that is vertical to the display surface.

The adjustment mechanism may move the display panel relative to the support base in parallel with the direction vertical to the display surface.

The adjustment mechanism may include a screw that is attached to the support base, and a connection member that is attached to the display panel and connected to the screw, and may adjust the distance by the screw being rotated relative to the connection member.

The screw may be rotatably attached to the support base. In this case, the adjustment mechanism may adjust the distance by the rotation of the screw.

The screw may be a female screw. In this case, the connection member may be a male screw that is fitted into the screw.

The screw may be a male screw. In this case, the connection member may be a female screw into which the screw is fitted.

The screw may be a male screw of which at least a tip is a magnetic body, and the tip of the screw may be movably attached to the support base by the rotation of the screw. In this case, the connection member may be a magnet that is brought into contact with the tip.

The adjustment mechanism may include a fixation member that rotatably holds the screw and is fixed to the support base. In this case, the screw and the connection member may be spaced from the support base.

The support base may include a flat plate portion that is arranged parallel to the display surface and in which a through hole is formed. In this case, the screw and the connection member are connected to each other through the through hole. Further, the through hole may have a diameter of a size such that the through hole is not brought into contact with the screw or the connection member.

The adjustment mechanism may include a biasing member that is arranged between the fixation member and the flat plate portion, the biasing member biasing the screw toward the fixation member.

The display panel may be rectangular as viewed from a direction that is vertical to the display surface. In this case, the adjustment mechanisms may be respectively arranged at positions of a plurality of positions on a peripheral edge of the display panel.

The adjustment mechanism may be arranged at each of four corners of the display panel.

Each of the plurality of positions may be situated in at least one portion between two ends of each of four side portions of the display panel.

The at least one display module may be a plurality of display modules. In this case, the display apparatus may further include a support member that supports the plurality of display modules.

The display panel may be rectangular as viewed from a direction that is vertical to the display surface. In this case, the support base may have a shape that is equal to the shape of the display panel as viewed from the direction vertical to the display surface. Further, each of the plurality of display modules may include at least one contact portion that is arranged at a peripheral edge of the support base and is brought into contact with the support member.

The at least one contact portion includes a contact surface that is brought into contact with the support member. In this case, the adjustment mechanism may adjust the distance in the direction vertical to the display surface such that a distance between the contact surface and the display surface exhibits a specified value.

The display module according to an embodiment of the present technology includes the display panel, the support base, and the adjustment mechanism.

### BRIEF DESCRIPTION OF DRAWINGS

FIG. 1 is a block diagram illustrating an example of a configuration of a display apparatus according to an embodiment of the present technology.

FIG. 2 schematically illustrates an example of a configuration of a display section.

FIG. 3 schematically illustrates an overview of a display unit.

FIG. 4 is an exploded perspective view of the display unit as viewed from the upper right on a front side of the display unit.

FIG. 5 is a perspective view of the display unit as viewed from the upper right on the front side, and illustrates the display unit from which a plurality of display modules has been removed.

FIG. 6 is an exploded perspective view of the display unit as viewed from the upper left on a rear side of the display unit.

FIG. 7 is an exploded perspective view of an enlarged upper right portion of the display unit as viewed from the front side.

FIG. 8 is an exploded perspective view of the enlarged portion illustrated in FIG. 7 as viewed from the rear side.

FIG. 9 is a cross-sectional view of a portion of the enlarged portion illustrated in FIG. 7 when the enlarged portion is cut along a plane (an XZ-plane) that is vertical to a Y direction and includes the center of a stepped screw in the enlarged portion.

FIG. 10 is a cross-sectional view of a portion of the display unit when an upper side portion of the display unit as viewed from the front side is cut along the plane (the XZ-plane) vertical to the Y direction.

FIG. 11 is a perspective view of the cross section illustrated in FIG. 10, as viewed from the rear side.

FIG. 12 is a perspective view illustrating an example of a configuration of a back surface portion of the display module.

FIG. 13 schematically illustrates an example of a configuration of the display module as viewed from the Y direction.

FIG. 14 is an exploded perspective view of the display module as viewed from the front side.

FIG. 15 is a cross-sectional view of a portion of the display module when an upper side portion of the display module is cut along the plane (the XZ-plane) being vertical to the Y direction and including the center of an adjustment mechanism.

FIG. 16 is an exploded perspective view of the display module as viewed from the rear side.

FIG. 17 is a cross-sectional view illustrating another example of a configuration of the adjustment mechanism.

FIG. 18 is a cross-sectional view illustrating another example of the configuration of the adjustment mechanism.

FIG. 19 is a perspective view of the unit base as viewed from the front side.

FIG. 20 is a schematic diagram used to describe a position of a Z positioning mechanism with respect to each display module.

FIG. 21 is a flowchart illustrating an example of a connection method for connecting a plurality of display units.

FIG. 22 is a perspective view of the unit bases as viewed from the upper right on a front side of the unit bases.

FIG. 23 is a perspective view of the unit bases as viewed from the upper right on the front side, and is an exploded perspective view of a unit base coupling plate.

FIG. 24 is a perspective view of the unit bases as viewed from the upper left on a rear side of the unit bases, and is an exploded perspective view of the unit base coupling plate.

FIG. 25 is a set of a perspective view and a cross-sectional view of enlarged portions of the unit bases as viewed from the front side, the enlarged portions being portions to which the unit base coupling plate is attached.

FIG. 26 illustrate another example of a configuration of the unit base coupling plate.

FIG. 27 illustrates a plurality of connected positioning members as viewed from a front side of the plurality of connected positioning members.

FIG. 28 is a perspective view of a plurality of positioning members as viewed from the upper left on the front side of the plurality of positioning members, and is an exploded perspective view of a positioning member coupling plate.

FIG. 29 is a perspective view of the plurality of positioning members as viewed from the upper left on a rear side of the plurality of positioning members, and is an exploded perspective view of the positioning member coupling plate.

FIG. 30 is a cross-sectional view of the plurality of positioning members to which the positioning member coupling plate is attached, the cross-sectional view being a cross-sectional view when the plurality of positioning members is cut along the plane (the XZ-plane) being vertical to the Y direction and including the center of the positioning member coupling plate.

FIG. 31 is a schematic diagram used to describe the connection of the positioning members using an assembling fixture.

FIG. 32 schematically illustrates the order of connecting the positioning members.

### MODE(S) FOR CARRYING OUT THE INVENTION

Embodiments according to the present technology will now be described below with reference to the drawings.

### Example of Configuration of Display Apparatus

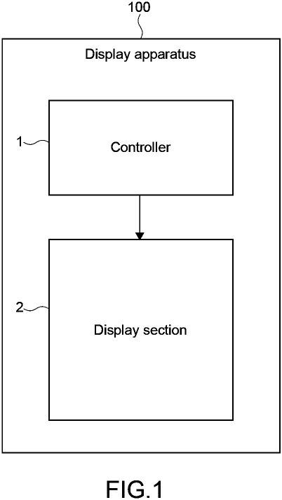

FIG. 1 is a block diagram illustrating an example of a configuration of a display apparatus 100 according to an embodiment of the present technology.

The display apparatus 100 is an apparatus that can display an image, and includes a controller 1 and a display section 2.

Note that, in the present disclosure, examples of the image include both a still image and a moving image (a video).

The controller 1 includes hardware, such as a processor such as a CPU, a GPU, and a DSP; a memory such as a ROM and a RAM; and a storage device such as an HDD, that is necessary for a configuration of a computer. For example, display of an image performed by the display apparatus 100 is performed by, for example, the CPU loading, into the RAM, a program according to the present technology that is recorded in, for example, the ROM in advance and executing the program.

A configuration of the controller 1 is not limited, and any hardware and any software may be used. Of course, hardware such as an FPGA or an ASIC may be used. Further, a position at which the controller 1 is implemented is also not limited, and designing may be performed discretionarily.

The program is installed on the display apparatus 100 through, for example, various recording media. Alternatively, the installation of the program may be performed via, for example, the Internet. The type and the like of a recording medium that records therein a program are not limited, and any computer-readable recording medium may be used. For example, any non-transitory computer-readable recording medium may be used.

For example, the controller 1 controls an operation of displaying an image that is performed by the display section 2.

For example, the controller 1 generates control signals such as a timing signal and a pixel signal, and supplies the generated control signals to the display section 2 through a signal line. Examples of the timing signal include a horizontal synchronization signal and a vertical synchronization signal. Further, examples of the pixel signal include signals that respectively represent gradation of red (R), gradation of green (G), and gradation of blue (B).

Moreover, various operations performed by the display apparatus 100 are controlled by the controller 1.

### Display Section

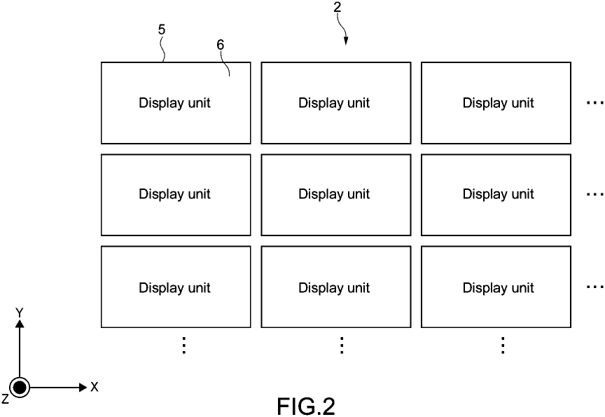

FIG. 2 schematically illustrates an example of a configuration of the display section 2.

In the present embodiment, the display section 2 includes a plurality of display units 5.

Each of the plurality of display units 5 includes an image display surface 6 that can display thereon an image. As illustrated in FIG. 2, the plurality of display units 5 is placed such that the image display surfaces 6 are arranged in a two-dimensional grid. This makes it possible to display an image on a large screen.

The controller 1 controls an operation of each display unit 5 such that a desired image such as one image is displayed on the image display surfaces 6 of the plurality of display units 5.

In the following description, as illustrated in FIG. 2, a right-and-left direction when a plurality of image display surfaces 6 is viewed from the front is referred to as an X direction and an up-and-down direction when the plurality of image display surfaces 6 is viewed from the front is referred to as a Y direction. Further, a depth direction (a direction vertical to the image display surface 6) when the plurality of image display surfaces 6 is viewed from the front is referred to as a Z direction.

Further, a side toward which an arrow of the X direction is oriented is referred to as a right side, and the opposite side is referred to as a left side. Furthermore, a side toward which an arrow of the Y direction is oriented is referred to as an upper side, and the opposite side is referred to as a lower side. Moreover, a side toward which an arrow of the Z direction is oriented is referred to as a backward side, and the opposite side is referred to as a forward side.

Of course, an orientation and the like of the display apparatus 100 in use when the present technology is applied are not limited.

In the example illustrated in FIG. 2, nine display units in total are arranged with three display units in the X direction (the right-and-left direction) and three display units in the Y direction (the up-and-down direction). The number of the plurality of display units 5 is not limited.

Further, the present technology can also be applied when the number of display units 5 is one. In other words, the present technology can be applied when at least one display unit 5 is arranged.

### Display Unit

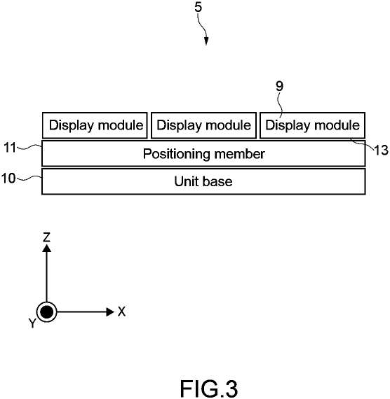

FIG. 3 schematically illustrates an overview of the display unit 5.

FIG. 3 schematically illustrates an example of a configuration of the display unit 5 as viewed from the Y direction.

The display unit 5 includes a plurality of display modules 9, a unit base 10, and a positioning member 11. In the example illustrated in FIG. 3, three display modules are arranged in the right-and-left direction, that is, in the X direction. Of course, the number of display modules 9 included in the display unit 5 is not limited.

For example, the present technology can also be applied when the number of display modules 9 is one. In other words, the present technology can be applied when at least one display module 9 is arranged.

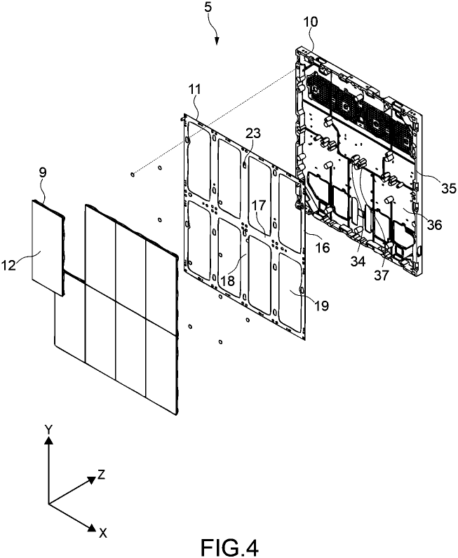

Each of the plurality of display modules 9 includes a display panel 12 that can display an image (refer to FIG. 4). The display panel 12 includes a display surface on which an image can be displayed. Any display device using, for example, liquid crystal or electroluminescence (EL) is adopted as the display panel 12.

As illustrated in FIG. 3, the plurality of display modules 9 is arranged such that the display surface of each of the plurality of display modules 9 is parallel to an XY-plane direction. Further, the plurality of display modules 9 is placed such that the display panels 12 of a plurality of display panels 12 are arranged in a two-dimensional grid.

The display surfaces of the display panels 12 arranged in a two-dimensional grid form the image display surface 6 of the display unit 5.

The unit base 10 supports the plurality of display modules 9. A back surface portion 13 of the display module 9 is supported by the unit base 10. Note that the back surface portion 13 of the display module 9 is a surface that is situated opposite to the display surface.

For example, at least a portion of the back surface portion 13 of the display module 9 may be brought in contact with the unit base 10. Alternatively, the entirety of the back surface portion 13 of the display module 9 may be connected to the positioning member 11, and the positioning member 11 may be supported by the unit base 10. In this case, the plurality of display modules 9 is supported by the unit base 10 through the positioning member 11.

The unit base 10 is formed using metal such as aluminum. Moreover, the material of the unit base 10 is not limited, and any material may be used.

The unit base 10 corresponds to an embodiment of a support member according to the present technology that supports at least one display module.

The positioning member 11 is arranged between the back surface portion 13 of the display module 9 and the unit base 10.

The positioning member 11 is a member that determines respective positions of the plurality of display modules 9 with respect to the unit base 10. In the present embodiment, a position in a direction (the XY-plane direction) that is parallel to the display surface of the display panel 12 is determined to be the position of each of the plurality of display modules 9.

In other words, positions of each display module 9 in the X direction and in the Y direction are determined by the positioning member 11.

The positioning member 11 is slidably connected to the unit base 10. In other words, the positioning member 11 is not completely fixed to the unit base, and is connected to the unit base such that the positioning member 11 can be slid in a specified range in the XY-plane direction.

Further, the plurality of display modules 9 is also supported by the unit base 10 to be slidable in the XY-plane direction.

Of course, the plurality of display modules 9 and the positioning member 11 are appropriately connected to the unit base 10 in order for the display unit 5 to not have a failure in displaying an image. On the other hand, the plurality of display modules 9 and the positioning member 11 are connected to the unit base 10 such that the plurality of display modules 9 and the positioning member 11 can be intentionally slightly slid with respect to the unit base 10.

The positioning member 11 is formed using, for example, carbon. Moreover, the material of the positioning member 11 is not limited, and any material may be used.

FIGS. 4 to 6 are perspective views each illustrating a specific example of a configuration of the display unit 5.

FIG. 4 is an exploded perspective view of the display unit 5 as viewed from the upper right on a front side of the display unit 5.

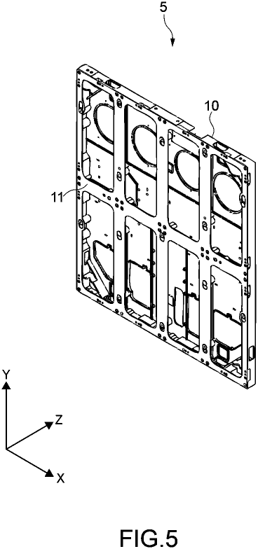

FIG. 5 is a perspective view of the display unit 5 as viewed from the upper right on the front side, and illustrates the display unit 5 from which a plurality of display modules 9 has been removed.

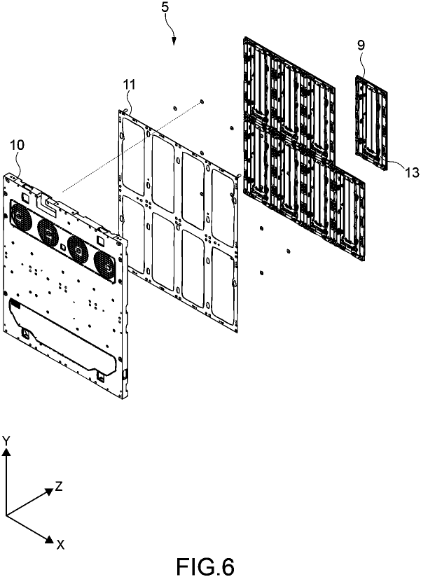

FIG. 6 is an exploded perspective view of the display unit 5 as viewed from the upper left on a rear side of the display unit 5.

As illustrated in FIGS. 4 to 6, the display unit 5 includes a plurality of display modules 9, the unit base 10, and the positioning member 11.

The entirety of the plurality of display modules 9, the unit base 10, and the positioning member 11 each generally have a shape of a flat plate. Further, the entirety of the plurality of display modules 9, the unit base 10, and the positioning member 11 respectively have outer shapes of substantially equal rectangles, as viewed from the Z direction.

As illustrated in FIGS. 4 and 6, the plurality of display modules 9, the unit base 10, and the positioning member 11 are assembled in the Z direction to form the display unit 5.

In the examples illustrated in FIGS. 4 and 6, eight display modules 9 in total are arranged, with four display modules 9 in the X direction (the right-and-left direction) and two display modules 9 in the Y direction (the up-and-down direction).

As illustrated in FIG. 4, the display module 9 includes a rectangular display panel 12, where the right-and-left direction is a lateral direction of the display panel 12 and the up-and-down direction is a longitudinal direction of the display panel 12. As viewed in the Z direction, the display module 9 has an outer shape of a rectangle that is similar to the shape of the display panel 12.

The unit base 10 includes a support mechanism that is used to support each of the eight display modules 9.

The support mechanism includes four contact reference surfaces and four magnets for one display module 9. These structural elements will be described in detail later.

Further, an attachment hole that is used to slidably hold the positioning member 11 is formed in the unit base 10.

The positioning member 11 includes an outer frame 16, a middle rib 17, and three partition ribs 18.

The outer frame 16 is a frame in the form of a hollow rectangle.

In the middle in the Y direction, the middle rib 17 extends in the X direction to be arranged inside of the outer frame 16.

The three partition ribs 18 extends in the X direction to be arranged inside of the outer frame such that the three partition ribs 18 are equally spaced in the Y direction.

Eight openings 19 that respectively correspond to the eight display modules 9 are formed by the outer frame 16, the middle rib 17, and the three partition ribs 18. In each opening 19, a portion that is situated at a peripheral edge of the opening 19 is a portion that corresponds to a peripheral edge of the back surface portion 13 of the display module 9.

As illustrated in FIG. 5, the positioning member 11 is connected to the unit base 10. As described above, the positioning member 11 is slidably connected to the unit base 10.

For this reason, a through hole is formed in the positioning member 11. Further, a stepped screw is used as a member used to slidably connect the positioning member 11 to the unit base 10.

### Connection of Positioning Member and Unit Base

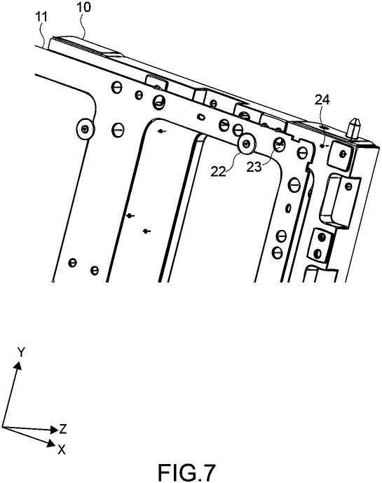

The connection of the positioning member 11 and the unit base 10 is described with reference to FIGS. 7 to 9.

FIGS. 7 to 9 primarily illustrate portions related to the connection of the positioning member 11 and the unit base 10, and illustration of a portion that is not related to the connection may be omitted.

In other words, when various features of the display apparatus 100 and the display unit 5 according to the present technology are descried in each figure, illustration of a portion related to a feature other than a description-target feature may be omitted in order to facilitate understanding of the description-target feature.

Further, when a plurality of figures is referred to upon describing a certain feature, illustration of each of a shape, a position, and the like may differ a little depending on each of the plurality of figures. In such a case, it can be said that all of the figures illustrate an embodiment according to the present technology.

FIG. 7 is an exploded perspective view of an enlarged upper right portion of the display unit 5 as viewed from the front side.

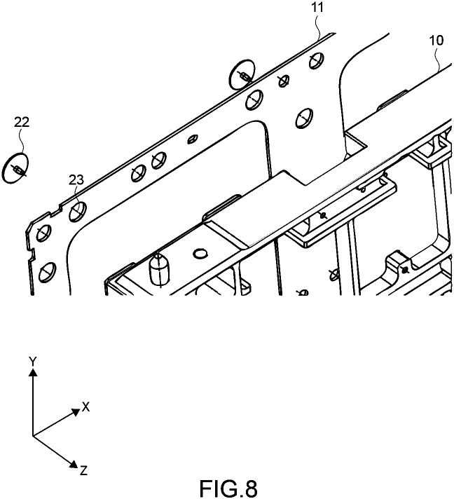

FIG. 8 is an exploded perspective view of the enlarged portion illustrated in FIG. 7 as viewed from the rear side.

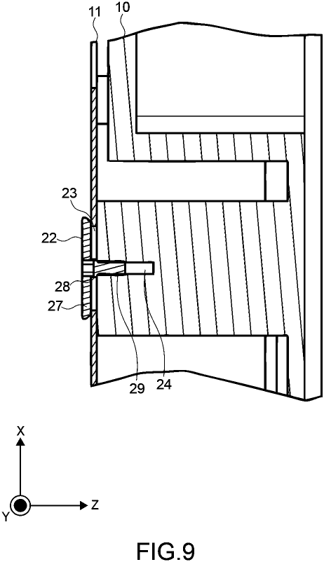

FIG. 9 is a cross-sectional view of a portion of the enlarged portion illustrated in FIG. 7 when the enlarged portion is cut along a plane (an XZ-plane) that is vertical to the Y direction and includes the center of a stepped screw 22 in the enlarged portion.

In the present embodiment, the positioning member 11 and the unit base 10 are connected to each other by the stepped screw 22. Specifically, the positioning member 11 and the unit base 10 are connected to each other by the stepped screw 22 passing through a through hole 23 formed in the positioning member 11 and being fitted into an attachment hole 24 formed in the unit base 10.

As illustrated in FIG. 7, a plurality of through holes 23 is formed in the positioning member 11.

In the present embodiment, a circular through hole 23 is formed. Of course, a specific shape of the through hole 23 is not limited.

In the example illustrated in FIG. 4, fifteen through holes 23 are formed for one positioning member 11.

The through hole 23 is formed in the outer frame 16 and the three partition ribs 18 of the positioning member 11.

As illustrated in FIG. 4, two through holes 23 are formed in a left side portion of the rectangular outer frame 16. The two through holes 23 are respectively formed at a position higher than the middle rib 17 in the Y direction, and at a position lower than the middle rib 17 in the Y direction.

Likewise, two through holes 23 in total are formed in a right side portion of the outer frame 16, where the two through holes 23 are respectively situated at a position higher than the middle rib 17 and at a position lower than the middle rib 17.

Four through holes 23 are formed in a leftmost partition rib 18 from among the three partition ribs 18. The two through holes 23 are formed at a position higher than the middle rib 17 in the Y direction, and the two through holes 23 are formed at a position lower than the middle rib 17 in the Y direction.

In the present embodiment, one of the two through holes 23 formed at the higher position is situated close to an upper side portion of the outer frame 16. Further, one of the two through holes 23 formed at the lower position is situated close to a lower side portion of the outer frame 16.

Likewise, four through holes 23 are formed in a rightmost partition rib 18 from among the three partition ribs 18.

Three through holes 23 are formed in a middle partition rib 18 from among the three partition ribs 18. The three through holes 23 are respectively formed close to the upper side portion of the outer frame 16, close to the lower side portion of the outer frame 16, and close to the middle rib 17.

In other words, fifteen through holes 23 in total are formed, where, as viewed from the front side, two through holes 23 are situated in the left side portion of the outer frame 16, two through holes 23 are situated in the right side portion of the outer frame 16, four through holes 23 are situated in the left partition rib 18, three through holes 23 are situated in the middle partition rib 18, and four through holes 23 are situated in the left partition rib 18.

Of course, the number of through holes 23 formed in the positioning member 11 and a position of the through hole 23 formed in the positioning member 11 are not limited.

In the examples illustrated in FIGS. 7 and 8, the through holes 23 are respectively formed close to a right end of the upper side portion of the outer frame 16, and close to an upper side portion of the right partition rib 18.

As illustrated in FIG. 7, a plurality of attachment holes 24 is formed in the unit base 10.

The attachment hole 24 is formed at a position that corresponds to the through hole 23 formed in the positioning member 11. For example, the attachment hole 24 is formed at a position that coincides with the center of the through hole 23 when the positioning member 11 is arranged at a desired position with respect to the unit base 10. Of course, without being limited thereto, the attachment hole 24 may be formed at a position offset from the center of the through hole 23.

In the present embodiment, a screw thread is formed in the attachment hole 24, where the screw thread is used such that the stepped screw 22 is fitted into the attachment hole 24.

In the example illustrated in FIG. 4, fifteen attachment holes 24 are formed at positions, in the unit base 10, that correspond to the respective through holes 23 of the positioning member 11.

Likewise, two attachment holes 24 are formed at positions, in the unit base 10 illustrated in FIG. 7, that respectively correspond to two through holes 23.

Of course, the number of attachment holes 24 formed in the unit base 10 and a position of the attachment hole 24 may be designed discretionarily according to the number of through holes 23 and a position of the through hole 23.

As illustrated in FIG. 9, the stepped screw 22 includes a head portion 27, a step portion 28, and a screw portion 29. The stepped screw 22 is attached to be oriented toward the rear side from the front side.

The head portion 27 has a shape of a disc. The head portion 27 includes a circular front surface and a circular rear surface.

The step portion 28 has a cylindrical shape. The step portion 28 is coupled to the center of the rear surface of the head portion 27 to extend rearwardly. The size of the step portion 28 in the Z direction is designed according to a thickness of the positioning member 11.

The screw portion 29 is coupled to the center of a rear end surface of the step portion 28 to extend rearwardly. A screw thread is formed in the screw portion 29 such that the screw thread of the screw portion 29 is fitted into the screw thread of the attachment hole 24 formed in the unit base 10.

When the stepped screw 22 is viewed from the front side, the screw portion 29 has a smaller diameter than the step portion 28, and the step portion 28 has a smaller diameter than the head portion 27. Thus, a step is formed in a coupling portion in which the step portion 28 and the screw portion 29 are coupled to each other.

The step portion 28 is configured to have a larger diameter than the attachment hole 24 into which the screw portion 29 is inserted to be fitted. Thus, when the stepped screw 22 is rotated to be fitted into the attachment hole 24, the rear end surface of the step portion 28 is brought into contact with a portion situated around the attachment hole 24 (that is, the unit base 10).

Further, the head portion 27 is larger than the through hole 23 in size. Specifically, the head portion 27 is configured to have a larger diameter than the through hole 23 formed in the positioning member 11.

The stepped screw 22 is formed using a metallic material such as iron. Of course, the material of the stepped screw 22 is not limited, and any material may be used. The stepped screw 22 corresponds to an embodiment of a fitting member according to the present technology that passes through a through hole to be fitted into an attachment hole, and slidably connects a positioning member to a support member.

As illustrated in FIG. 9, the stepped screw 22 passes through the through hole 23 formed in the positioning member 11 to be fitted into the attachment hole 24 formed in the unit base 10. This results in the positioning member 11 being fixed by being sandwiched between the head portion 27 of the stepped screw 22 and the unit base 10.

In the present embodiment, the stepped screw 22 is fitted into the attachment hole 24 such that the positioning member 11 can be slid with respect to the unit base 10 in the X direction and in the Y direction. For example, the adjustment of the size of the step portion 28 in the Z direction makes it possible to connect the positioning member 11 to the unit base 10 such that the positioning member 11 is fixed too strongly or too weakly.

Of course, an amount of rotation of the stepped screw 22 when the stepped screw 22 is fitted into the attachment hole 24 may be adjusted.

A slidable range in which the positioning member 11 can be slid with respect to the unit base 10 may be determined.

In the example illustrated in, for example, FIG. 9, the slidable range of the positioning member 11 can be determined by the diameter of the through hole 23 formed in the positioning member 11.

The slidable range can be made larger by making the diameter of the through hole 23 larger. Further, the slidable range can be made smaller by making the diameter of the through hole 23 smaller. As described above, the slidable range may be determined by the diameter (or a radius) of the through hole 23.

Moreover, any configuration used to determine the slidable range of the positioning member 11 may be adopted.

A biasing member such as a spring may be used in order to slidably connect the positioning member 11 to the unit base 10. For example, the stepped screw 22 is biased by the biasing member toward the unit base 10. The appropriate adjustment of a biasing force of the biasing member makes it possible to adjust a pressing force with which the head portion 27 of the stepped screw 22 presses the positioning member 11.

Moreover, any configuration may be adopted in order to set the pressing force such that the pressing force exhibits a suitable magnitude.

When the positioning member 11 is slidably connected to the unit base 10, this makes it possible to prevent the positioning member 11 from being affected by, for example, deformation of the unit base 10.

For example, the unit base 10 is formed using metal such as aluminum. Further, the positioning member 11 is formed using, for example, carbon. Metal such as aluminum has a higher coefficient of thermal expansion than, for example, carbon, and the rate of change in surface area with a change in temperature is increased. Thus, when, for example, there is an increase in the temperature of a space in which the display apparatus 100 is placed, the surface area of the unit base 10 is more greatly increased than the surface area of the positioning member 11.

Even when the unit base 10 is deformed due to such a difference in coefficient of thermal expansion, the positioning member 11 is relatively slipped to be slid with respect to the unit base 10. This makes it possible to prevent stress caused in response to the deformation of the unit base 10 from being applied to the positioning member 11.

Note that the slidable range of the positioning member 11 may be set in consideration of an amount of deformation of the unit base 10.

For example, the slidable range is made larger by making the diameter of the through hole 23 illustrated in FIG. 9 larger. This makes it possible to also prevent the positioning member 11 from being affected when the unit base 10 is greatly deformed.

Further, when the amount of deformation of the unit base 10 is expected to be small, the diameter of the through hole 23 may be intentionally set small.

### Attachment of Plurality of Display Modules

The positioning member 11 is slidably connected to the unit base 10, as illustrated in FIG. 5. A plurality of display modules 9 is attached on the basis of the positioning member 11 connected to the unit base 10.

In the example illustrated in FIG. 4, eight display modules 9 are respectively attached at positions of eight openings 19 formed in the positioning member 11.

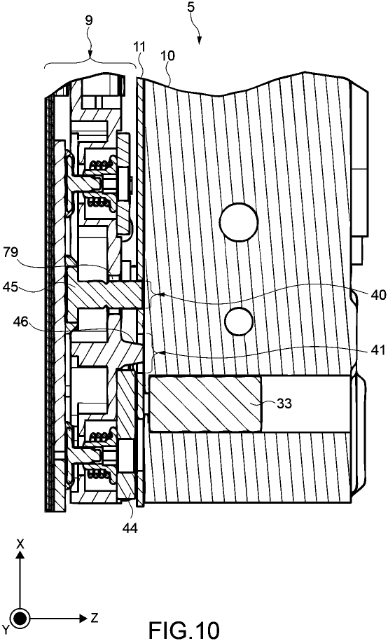

FIG. 10 is a cross-sectional view of a portion of the display unit 5 when an upper side portion of the display unit 5 as viewed from the front side is cut along the plane (the XZ-plane) vertical to the Y direction. Further, FIG. 10 corresponds to a cross-sectional view of a portion around an upper right corner of the display unit 5.

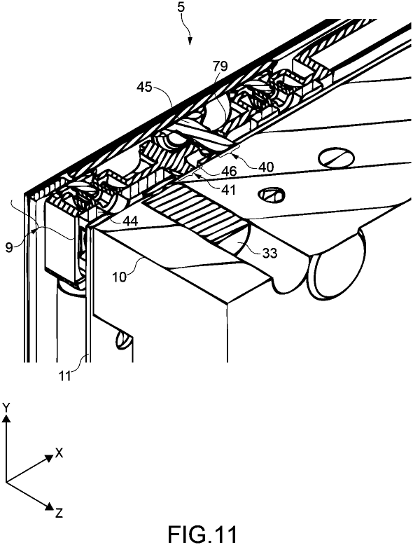

FIG. 11 is a perspective view of the cross section illustrated in FIG. 10, as viewed from the rear side.

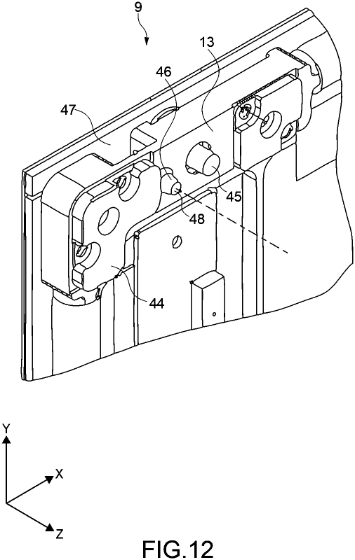

FIG. 12 is a perspective view illustrating an example of a configuration of the back surface portion 13 of the display module 9. FIG. 12 corresponds to a diagram of an upper right corner of an upper right display module 9 from among the eight display modules 9 illustrated in FIG. 4, as viewed from the rear side.

A support mechanism used to support the display module 9 is arranged in the unit base 10.

The support mechanism is arranged for each display module 9. Specifically, the support mechanism is arranged in a portion, in the unit base 10, that corresponds to a peripheral edge of each opening 19, and supports the display module 9.

In the present embodiment, the support mechanism includes four magnets 33 and four contact reference surfaces 34.

The four magnets 33 are embedded in portions, in the unit base 10, that respectively correspond to four corners of the opening 19. Thus, 32 magnets 33 in total are placed in the unit base 10.

Likewise, the four contact reference surfaces 34 are arranged in portions that respectively correspond to the four corners of the opening 19. Thus, the magnet 33 and the contact reference surface 34 are situated close to each other.

In the example illustrated in FIG. 4, the unit base 10 includes an outer frame 35 and a bottom surface portion 36. The outer frame 35 is rectangular when the unit base 10 is viewed from the Z direction. The bottom surface portion 36 has a shape of a plane vertical to the Z direction, and is coupled to a rear side of the outer frame 35. A space that is situated inside of the outer frame 35 and on a front side of the bottom surface portion 36 is a space that supports a plurality of display modules 9.

As illustrated in FIG. 4, a support convex portion 37 that extends forwardly in the Z direction is arranged in a specified portion in the bottom surface portion 36. Support convex portions 37 of a plurality of support convex portions 37 are arranged in portions that respectively correspond to the four corners of each opening 19. Each of the plurality of support convex portions 37 is a structural element that is included in the support mechanism.

In the present embodiment, the magnet 33 is embedded in a portion, in the outer frame 35, that corresponds to each of the four corners of each opening 19. Further, the magnets 33 are respectively embedded in the respective support convex portions 37 arranged in the respective portions respectively corresponding to the four corners of each opening 19.

Further, the contact reference surface 34 is formed in a portion that is situated on a front surface of the outer frame 35 and corresponds to each of the four corners of each opening 19 (a portion close to the magnet 33). Furthermore, the contact reference surface 34 is formed on a front surface of the support convex portion 37 arranged in the portion corresponding to each of the four corners of each opening 19.

The contact reference surface 34 is precisely processed by machining with respect to its height measured from the bottom surface portion 36 and its flatness. Contact reference surfaces 34 of a plurality of contact reference surfaces 34 formed in the outer frame 35 and the support convex portion 37 are formed in plane with each other with a high degree of accuracy.

As illustrated in FIGS. 10 and 11, the positioning member 11 includes at least one mark, for each display module 9, that is formed in a specified portion in the positioning member 11. The at least one mark is a mark used as a reference when the display module 9 is arranged with respect to the unit base 10.

In the present embodiment, a positioning hole 40 is formed as the mark at a peripheral edge of the opening 19. For example, the positioning hole 40 is formed at each of four corners of the peripheral edge of the opening 19. Alternatively, the positioning hole 40 is formed at each of two ends of one of side portions of the peripheral edge of the opening 19. Any other configuration may be adopted.

Further, the positioning member 11 includes four contact through holes 41 for each display module 9. The contact through hole 41 is formed in a portion, at each of the four corners of the opening 19, that corresponds to each of the four contact reference surfaces 34 of the unit base 10.

When the positioning member 11 is connected to the unit base 10, the four contact reference surfaces 34 of the unit base 10 can be seen through the respective four contact through holes 41.

On the other hand, when the positioning member 11 is connected to the unit base 10, the four magnets 33 embedded in the unit base 10 are covered with the positioning member 11.

As illustrated in FIG. 12, a magnetic body member 44, a positioning pin 45, and a contact convex portion 46 are arranged in the back surface portion 13 of the display module 9.

The magnetic body member 44 is placed at each of four corners of the back surface portion 13. The magnetic body member 44 is placed in a portion that corresponds to each of the four magnets 33 embedded in the unit base 10.

The positioning pin 45 is placed in a portion that corresponds to the positioning hole 40 formed in the positioning member 11.

In the example illustrated in FIG. 12, a reinforcement member 47 is provided on a rear side of the display panel 12 in each display module 9.

The display panel 12 is formed using a material, such as glass, that exhibits a low degree of strength. When the reinforcement member 47 is connected to the display panel 12, this results in increasing the strength of the display panel 12, and thus in preventing the display panel 12 from being broken up due to impact.

The reinforcement member 47 is formed using a rigid material such as carbon. Of course, a specific configuration of the reinforcement member 47 such as the material and the shape of the reinforcement member 47 is not limited.

The positioning pin 45 is fixed to the reinforcement member 47.

For example, the positioning pin 45 is fixed to the reinforcement member 47 by bonding using, for example, an adhesive. Moreover, any fixation method that enables the positioning pin 45 to be fixed to the reinforcement member 47 may be adopted.

The positioning pin 45 corresponds to an embodiment of a pin member according to the present technology.

A contact reference surface 48 is arranged at a rear end of the contact convex portion 46. In the present embodiment, four contact convex portions 46 are formed in portions that respectively correspond to the four contact through holes 41 formed in the positioning member 11. In other words, the four contact convex portions 46 are formed in portions that respectively correspond to the four contact reference surfaces 34 of the unit base 10.

The contact convex portion 46 is precisely processed by machining with respect to the height of the contact convex portion 46. In other words, the position of the contact reference surface 48 in the Z direction is precisely determined. Further, the contact reference surface 48 is also precisely processed by machining with respect to the flatness of the contact reference surface 48. Contact reference surfaces 48 of a plurality of contact reference surfaces 48 in each display module 9 are formed in plane with each other with a high degree of accuracy.

Each of the eight display modules 9 is arranged with respect to the unit base 10 such that the positioning pin 45 is fitted into the positioning hole 40 formed in the positioning member 11.

This results in each of four magnets 33 embedded in the unit base 10 and each of four magnetic body members 44 arranged in the back surface portion 13 of the display module 9 sticking to each other by a magnetic force. As illustrated in FIGS. 10 and 11, the magnet 33 and the magnetic body member 44 stick to each other in a state in which the positioning member 11 is situated between the magnet 33 and the magnetic body member 44.

As described above, each of the eight display modules 9 is supported by the unit base 10 due to a magnetic force that acts between the magnet 33 and the magnetic body member 44. Thus, the display module 9 is connected to be slidable with respect to the unit base 10 in the X direction and in the Y direction.

Any metallic material such as iron may be used for a magnetic body. Of course, any other magnetic body material may be used. For example, a magnet may be used to stick to the magnet 33 embedded in the unit base.

Further, each of the four contact reference surfaces 34 of the unit base 10 and each of the four contact reference surfaces 48 arranged in the back surface portion 13 of the display module 9 are brought into contact with each other.

A position of each display module 9 with respect to the unit base 10 in the Z direction is determined by the contact reference surface 34 and the contact reference surface 48 being brought into contact with each other. Since the height and the flatness of the contact reference surface 34 and the contact reference surface 48 are precisely determined, the position of each display module 9 is determined in the Z direction with a high degree of accuracy. Further, the display surfaces of the respective display modules 9 are also aligned with each other in the XY-plane direction with a high degree of accuracy.

Of course, the contact reference surface 34 and the contact reference surface 48 may be designed discretionarily with respect to, for example, their heights.

In the present embodiment, the positioning pin 45 is fitted into the positioning hole 40 with no space, as illustrated in FIGS. 10 and 11. This makes it possible to accurately determine the positions in the X direction and in the Y direction. Further, the positioning member 11 and a plurality of display modules 9 can be integrally slid with respect to the unit base 10.

In the Z direction, a length of the positioning pin 45 is set such that some space is created between the positioning pin 45 and the unit base 10. In other words, the length of the positioning pin 45 in the Z direction is set such that a tip of the positioning pin 45 is not brought into contact with a front surface of the unit base 10 when the display unit 5 is assembled.

This results in preventing interruption of contact between the contact reference surface 34 and the contact reference surface 48, the contact serving to determine the position of the display module 9 in the Z direction. Of course, the length of the positioning pin 45 is determined in a range in which the positions in the X direction and in the Y direction can be determined.

In the present embodiment, the display module 9 is fixed to the positioning member 11 by the positioning pin 45 being fitted into the positioning hole 40. Further, the display module 9 and the positioning member 11 can be integrally slid with respect to the unit base 10.

Thus, when, for example, the unit base 10 is deformed due to, for example, a change in temperature, a plurality of display modules 9 and the positioning member 11 can be integrally relatively slipped to be slid with respect to the unit base 10. This makes it possible to prevent stress caused in response to the deformation of the unit base 10 from being applied to the plurality of display modules 9 and the positioning member 11.

Any configuration may be adopted as a configuration of the mark formed in the positioning member 11.

For example, the positioning pin 45 may be formed in the positioning member 11. Then, the positioning hole 40 may be formed in the display module 9. In this case, each display module 9 is arranged with respect to the unit base 10 such that the positioning pin 45 formed in the positioning member 11 is fitted into the positioning hole 40. This makes it possible to accurately determine the positions of the display module 9 in the X direction and in the Y direction.

Any other configuration may be adopted.

The positioning member 11 and the display module 9 may be connected to each other by, for example, fastening using a fastening member such as a screw, or bonding using, for example, an adhesive, or welding. In this case, the display module 9 and the positioning member 11 are also integrally slidable with respect to the unit base 10. This makes it possible to prevent stress caused in response to the deformation of the unit base 10 from being applied to the plurality of display modules 9 and the positioning member 11.

For example, the display module 9 can be connected to the positioning member 11 while the positions of the display module 9 in the X direction and in the Y direction are determined by, for example, appropriately designing, for example, a position of attaching a fastening member or a position of applying an adhesive. In this case, for example, a screw hole, or a concave portion to which an adhesive is applied can also serve as an embodiment of a mark according to the present technology.

The mark used as a reference when the display module 9 is arranged with respect to the unit base 10, as described above, is not limited, and, for example, any member or any bonding point may be used as the mark. Further, a method for arranging the display module 9 using a mark arranged in the positioning member as a reference is also not limited, and any method may be adopted.

### Display Module

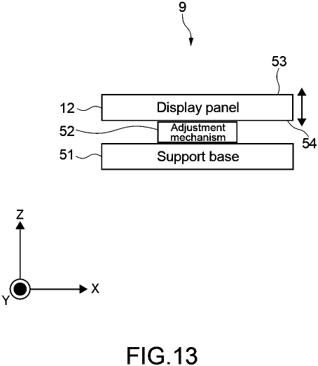

An overview of display module 9 is described with reference to FIG. 13.

FIG. 13 schematically illustrates an example of a configuration of the display module 9 as viewed from the Y direction.

The display module 9 includes the display panel 12, a support base 51, and an adjustment mechanism 52.

The display panel 12 includes a display surface 53 and a rear surface 54 that is situated opposite to the display surface 53.

The support base 51 supports the display panel 12. The rear surface 54 of the display panel 12 is supported by the support base 51. In the example illustrated in FIG. 12, the reinforcement member 47 is connected to the rear surface 54 of the display panel 12. The support base 51 supports the display panel 12 through the reinforcement member 47.

Further, in the example illustrated in FIG. 12, the contact convex portion 46 including the contact reference surface 48 is formed on the rear surface 54 of the support base 51.

The support base 51 is formed using metal such as aluminum. Moreover, the material of the support base 51 is not limited, and any material may be used.

The adjustment mechanism 52 is connected to the display panel 12 and to the support base 51, and can adjust a relative distance of the display panel 12 to the support base 51. For example, in the example illustrated in FIG. 12, the adjustment mechanism 52 can adjust a distance between the contact reference surface 48 formed in the support base 51 and the display surface 53 of the display panel 12.

As described above, in the example illustrated in, for example, FIG. 12, the position of the display module 9 in the Z direction with respect to the unit base 10 is determined by the contact reference surface 48 of the contact convex portion 46 formed in the support base 51 and the contact reference surface 34 of the support convex portion 37 formed in the unit base 10 being brought into contact with each other.

In the present embodiment, the adjustment mechanism 52 can further adjust a position of the display panel 12 in the Z direction with respect to the support base 51. This results in being able to adjust, for example, the position and inclination of the display surface 53 of the display panel 12 in the Z direction.

This makes it possible to arrange the respective display surfaces 53 in one plane when, for example, the display panels 12 of a plurality of display panels 12 are placed side by side, as illustrated in FIG. 4.

### Adjustment Mechanism

The adjustment mechanism 52 is described with reference to FIGS. 10 to 12, and FIGS. 14 to 16.

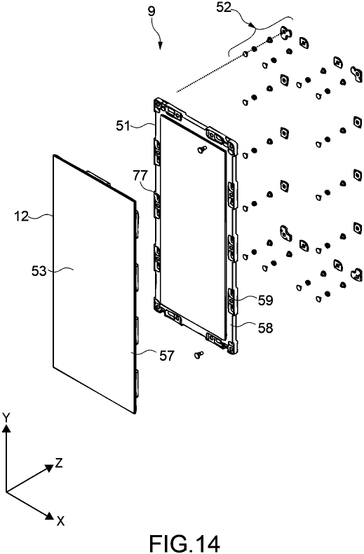

FIG. 14 is an exploded perspective view of the display module 9 as viewed from the front side.

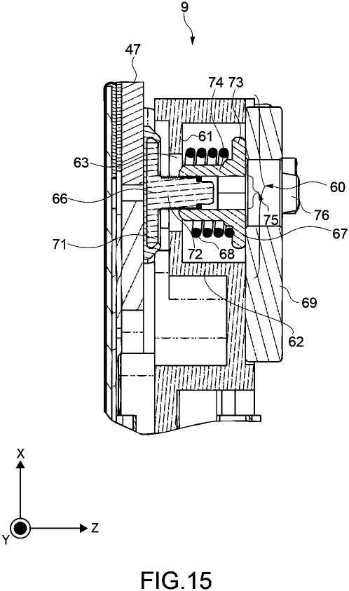

FIG. 15 is a cross-sectional view of a portion of the display module 9 when an upper side portion of the display module 9 is cut along the plane (the XZ-plane) being vertical to the Y direction and including the center of the adjustment mechanism 52. FIG. 15 is a cross-sectional view of a portion situated close to an upper left corner of the display module 9.

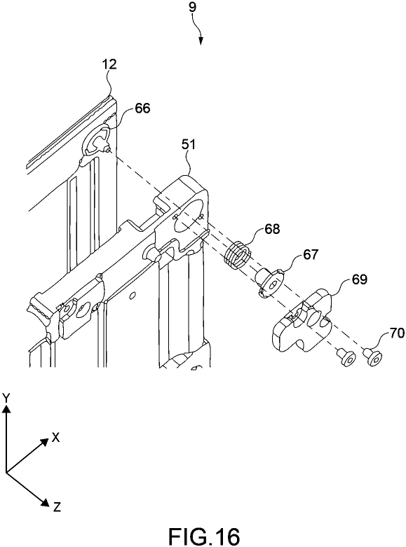

FIG. 16 is an exploded perspective view of the display module 9 as viewed from the rear side. FIG. 16 is an exploded perspective view of an upper right portion of the display module 9.

As illustrated in FIG. 14, the display panel 12 and the support base 51 respectively have outer shapes of substantially equal rectangles, as viewed from a direction (the Z direction) that is vertical to the display surface 53. Thus, a peripheral edge 57 of the display panel 12 is supported by a peripheral edge 58 of the support base 51.

In the present embodiment, fourteen adjustment mechanisms 52 in total are arranged between the peripheral edge 57 of the display panel 12 and the peripheral edge 58 of the support base 51.

As illustrated in FIGS. 14 and 15, an attachment mechanism 59 used to attach the adjustment mechanism 52 is arranged at the peripheral edge 58 of the support base 51.

The attachment mechanism 59 includes an attachment concave portion 60 that is forwardly curved when the support base 51 is viewed from the rear side. The attachment concave portion 60 has a circular outer shape, as viewed from the rear side in the Z direction.

The attachment concave portion 60 includes a flat plate portion 61 that corresponds to a bottom surface of a concave portion, and a sidewall portion 62 that extends rearward from the flat plate portion 61. The flat plate portion 61 is a flat-plate-shaped member that is arranged parallel to the display surface 53.

Further, an adjustment-mechanism through hole 63 used to attach the adjustment mechanism 52 is formed in the attachment concave portion 60 of the attachment mechanism 59.

The attachment mechanism 59 is formed in the following fourteen portions.
Four corners of the peripheral edge 58 (four portions)
Two portions, in each of two short sides (an upper side portion and a lower side portion) of the peripheral edge 58, that are situated closer to the middle than two ends of each short side (four portions in total)
Three portions, in each of two long sides (a left side portion and a right side portion) of the peripheral edge 58, that are situated closer to the middle than two ends of each long side (six portions in total)

The attachment mechanism 59 is formed in at least one portion situated between the two ends of each of the short side and the long side of the peripheral edge 58. Note that the two ends of each of the short side and the long side respectively correspond to two of the four corners of the peripheral edge 58.

As illustrated in FIG. 14, the two portions, in each of the two short sides of the peripheral edge 58, that are situated closer to the middle are two portions that are each substantially intermediate between the end and the middle.

The three portions, in each of the two long sides of the peripheral edge 58, that are situated closer to the middle are a portion in the middle and two portions that are each substantially intermediate between the end and the middle.

When the display module 9 is viewed from the front, a position of the adjustment-mechanism through hole 63 corresponds to a position of the adjustment mechanism 52. The position of the adjustment mechanism 52 and the number of adjustment mechanisms 52 for one display module 9 are not limited, and may be designed discretionarily.

In the present embodiment, the adjustment mechanism 52 includes a male screw stud 66, a female screw 67, a torsional coil spring 68, a lid member 69, and a lid retaining screw 70.

The male screw stud 66 includes a head portion 71, and a male screw portion 72 in which a screw thread is formed. The male screw portion 72 is coupled to the center of the head portion 71.

The head portion 71 of the male screw stud 66 is provided to the reinforcement member 47 connected on the rear side of the display panel 12, such that the male screw portion 72 extends rearwardly. The male screw stud 66 is connected to the reinforcement member 47 such that a central axis of the male screw stud 66 coincides with a line that passes through the center of the adjustment-mechanism through hole 63.

The head portion 71 of the male screw stud 66 is fixed to the reinforcement member 47 by fastening using a fastening member such as a screw. Moreover, any fixation method, such as bonding using an adhesive, or welding, that enables the male screw stud 66 to be fixed to the reinforcement member 47 may be adopted.

The male screw stud 66 is formed using a metallic material such as iron. Of course, the material of the male screw stud 66 is not limited, and any material may be used.

The male screw stud 66 corresponds to an embodiment of a connection member according to the present technology that is attached to a display panel and connected to a screw.

The female screw 67 includes a head portion 73 and a hollow cylindrical portion 74. The hollow portion of the cylindrical portion 74 is formed as a screw hole that is engaged with the male screw portion 72. Further, a through hole 75 is formed in a center portion of the head portion 73, and is linked to the screw hole.

The female screw 67 is arranged inside of the attachment concave portion 60 such that the cylindrical portion 74 extends forwardly. The female screw 67 is arranged such that a central axis of the female screw 67 coincides with the line passing through the center of the adjustment-mechanism through hole 63, that is, such that the central axis of the female screw 67 coincides with the central axis of the male screw stud 66.

In the present embodiment, the head portion 73 of the female screw 67 is attached to a front surface of the lid member 69. Further, a rotation member 76 situated on a rear side of the lid member 69 is connected to the female screw 67 in a state in which the lid member 69 is situated between the rotation member 76 and the female screw 67. In the example illustrated in FIG. 15, a front end of the rotation member 76 is inserted into the through hole 75 of the head portion 73 of the female screw 67 to be fixed. The female screw 67 and the rotation member 76 can be rotated with respect to the lid member 69.

For example, a groove (such as a cross-shaped groove or a straight-shaped groove) that can be engaged with the head of a screwdriver is formed on a rear surface of the rotation member 76. A user can rotate the female screw 67 by rotating the rotation member 76 using, for example, a screwdriver. Of course, any other configuration may be adopted as a configuration for rotating the female screw 67.

Note that, in FIG. 16, illustration of the rotation member 76 is omitted.

The female screw 67 is formed using a metallic material such as iron. Of course, the material of the female screw 67 is not limited, and any material may be used.

The female screw 67 corresponds to an embodiment of a screw according to the present technology that is attached to a support base.

The lid member 69 is connected to the support base 51 such that the female screw 67 attached on a front side of the lid member 69 is arranged in a center portion of the attachment concave portion 60.

In the example illustrated in, for example, FIG. 14, the lid member 69 is connected to the support base 51 respectively using the lid retaining screws 70 in two specified locations around the attachment concave portion 60.

As illustrated in FIG. 15, the lid member 69 of the adjustment mechanism 52 arranged at each of four corners of the support base 51 and the lid member 69 of the adjustment mechanism 52 arranged in a portion adjacent to the adjustment mechanism 52 at the corner of the support base 51 have different shapes, as viewed from the Z direction. With respect to a member included in the adjustment mechanism 52, the shape and the like of the member may differ depending on each adjustment mechanism 52, as described above.

In the present embodiment, the lid member 69 is a member that corresponds to the magnetic body member 44 illustrated in, for example, FIG. 12. In other words, in the present embodiment, the lid member 69 and the magnet 33 embedded in the unit base 10 stick to each other. As described above, the member included in the adjustment mechanism 52 may serve as a member used to connect the display unit 5 to the unit base 10. This makes it possible to reduce the number of components and to make the configuration simpler.

The lid member 69 is formed using a metallic material such as iron. Of course, the material of the lid member 69 is not limited, and any material may be used.

The lid member 69 corresponds to an embodiment of a fixation member according to the present technology that rotatably holds a screw and is fixed to a support base. The female screw 67 is rotatably attached to the support base 51 through the lid member 69.

The torsional coil spring 68 is arranged inside of the attachment concave portion 60 between the flat plate portion 61 and the lid member 69. One of two ends of the torsional coil spring 68 is connected to the flat plate portion 61, and another of the two ends is connected to the head portion 73 of the female screw 67. Thus, the female screw 67 is biased by the torsional coil spring 68 toward the lid member 69. This makes it possible to prevent looseness (backlash) from being caused between the male screw portion 72 and the female screw 67.

A specific material and a specific shape of the torsional coil spring 68 are not limited. The torsional coil spring 68 corresponds to an embodiment of a biasing member according to the present technology that is arranged between a fixation member and a flat plate portion and biases a screw toward the fixation member.

Note that a member used to bias the female screw 67 toward the lid member 69 is not limited to the torsional coil spring 68. For example, the female screw 67 may be biased toward the lid member 69 using, for example, a disc spring or rubber. Moreover, the biasing method is not limited, and any method may be adopted.

As illustrated in, for example, FIG. 15, the male screw stud 66 and the female screw 67 are connected to each other through the adjustment-mechanism through hole 63. In the example illustrated in FIG. 15, the male screw portion 72 of the male screw stud 66 passes through the through hole 63 to extend rearwardly. Of course, without being limited thereto, the cylindrical portion 74 of the female screw 67 may passe through the through hole 63.

When the lid member 69 is attached to the support base 51, the rotation member 76 is rotated as appropriate to fit the male screw stud 66 into the female screw 67. Then, the lid member 69 is fixed to the support base 51 using the lid retaining screw 70.

Note that, as illustrated in, for example, FIG. 14, a positioning-pin through hole 77 through which the positioning pin 45 passes is formed at the peripheral edge of the support base 51. The positioning-pin through hole 77 is formed in a portion to which the positioning pin 45 is attached.

### Adjustment of Height of Display Panel That Is Performed by Adjustment Mechanism

An adjustment of a height of the display panel 12 that is performed by the adjustment mechanism 52 is described with reference to FIG. 15.

In the present embodiment, a relative distance of the display panel 12 to the support base 51 in a direction that is vertical to the display surface of the display panel 12 is adjusted by the adjustment mechanism 52.

In the following description, the adjustment of the relative distance of the display panel 12 to the support base 51 in a direction that is vertical to the display surface 53 may be referred to as an adjustment of a height of the display panel 12 with respect to the support base 51, or may be simply referred to as an adjustment of the height of the display panel 12.

In the present embodiment, the height of the display panel 12 is adjusted by the female screw 67 being rotated relative to the male screw stud 66.

For example, the rotation member 76 is rotated using a tool such as a screwdriver. The rotation member 76 and the female screw 67 are connected to each other. Thus, the female screw 67 is also rotated integrally with the rotated rotation member 76.

The male screw stud 66 is fixed to the reinforcement member 47 in order for the male screw stud 66 to not be rotated. Thus, the rotation of the female screw 67 results in adjusting a fitting position (a fitting depth) at which the male screw stud 66 is fitted into the female screw 67. Thus, a front end of the male screw stud 66 is forwardly or rearwardly moved relative to the female screw 67.

For example, when the female screw 67 is rotated clockwise, the male screw stud 66 is moved forwardly. When the female screw 67 is rotated counterclockwise, the male screw stud 66 is moved rearwardly. Of course, the relationship between the direction of rotating the female screw 67 and the direction of moving the male screw stud 66 in parallel with the Z direction may be the reverse of the relationship described above.

The female screw 67 is fixed to the support base 51 through the lid member 69. Further, the male screw stud 66 is fixed to the reinforcement member 47. Thus, when the male screw stud 66 is moved forwardly or rearwardly in the Z direction, the relative distance of the display panel 12 to the support base 51 in the direction vertical to the display surface of the display panel 12 is adjusted.

In the present embodiment, the clockwise rotation of the female screw 67 enables the display surface 53 of the display panel 12 to be moved rearwardly. The counterclockwise rotation of the female screw 67 enables the display surface 53 of the display panel 12 to be moved forwardly.

In other words, in the present embodiment, the clockwise rotation of the female screw 67 makes it possible to reduce the height of the display panel 12 with respect to the support base 51. Further, the counterclockwise rotation of the female screw 67 makes it possible to increase the height of the display panel 12 with respect to the support base 51. As described above, the rotation of the female screw 67 results in adjusting the height of the display panel 12 with respect to the support base 51.

The height of the display panel 12 is adjusted using, for example, a dedicated fixture before the display module 9 is attached to the unit base 10. For example, the support base 51 is fixed using a fixture, and the female screw 67 of each adjustment mechanism 52 is rotated. Of course, the adjustment method is not limited to such an adjustment method.

In the example illustrated in FIG. 14, fourteen adjustment mechanisms 52 are provided to the display panel 12 and the peripheral edge 58 of the support base 51. When the female screw 67 is rotated in each adjustment mechanism 52, this makes it possible to adjust the height of the display panel 12 in portions in which the adjustment mechanisms 52 are provided.

For example, a distance between the contact reference surface 48 of the contact convex portion 46 illustrated in, for example, FIG. 12 and the display surface 53 is determined to be the height of the display panel 12. Further, a design value for the height of the display panel 12 is determined.

The adjustment mechanisms 52 arranged in the fourteen portions are operated after the display panel 12 and the support base 51 are connected to each other. This makes it possible to adjust the height of the display panel 12 to the design value in the entirety of a region of the display surface 53. Note that the design value corresponds to a specified value.

In the present embodiment, eight display modules 9 are arranged for one unit base 10.

The adjustment mechanisms 52 are operated in each of the plurality of display modules 9 in advance when the display unit 5 is assembled. This results in adjusting the height of the display panel 12 to the design value. In other words, the heights of the display panels 12 of the respective display modules 9 are adjusted to be equal before the display modules 9 are attached to the unit base 10.

The plurality of display modules 9 respectively including the display panels 12 of equal heights is connected to the unit base 10 using the positioning member 11 as a reference. The contact reference surface 48 in the display module 9 and the contact reference surface 34 of the unit base 10 are brought into contact with each other to determine the position of the display module 9 with respect to the unit base 10 in the Z direction.

The heights of the display panels 12 of the respective display modules 9 are adjusted to be equal. Thus, the display surfaces 53 of the eight display modules 9 are arranged in one plane. This makes it possible to display a high-quality image.

It is assumed that, for example, the display panels 12 of the respective display modules 9 have different heights, and the display surfaces 53 are not arranged in one plane. In this case, due to, for example, a difference in level between adjacent display surfaces 53, a user may recognize a bright line or a dark line upon viewing an image displayed by the display apparatus 100.

It is assumed that, for example, a right display surface 53 of one of two display panels 12 that are arranged side by side is situated further forward than a left display surface 53 of another of the two display panels 12. When a user views the display apparatus 100 from a location ahead on the right, a right-end portion of the left display panel 12 is blocked by a left-end portion of the right display panel 12. Consequently, a dark line is caused in a joint portion of the right display panel 12 and the left display panel 12, and the user views the caused dark line.

Likewise, a bright line is caused due to a difference in level between the adjacent display surfaces 53.

In the display apparatus 100 according to the present technology, display surfaces 53 of a plurality of display surfaces 53 are easily arranged in one plane by operating the adjustment mechanisms 52. This makes it possible to sufficiently suppress the occurrence of a bright line and a dark line, and thus to display a high-quality image.

Further, when the adjustment mechanisms 52 are respectively arranged at positions of a plurality of positions, as in the present embodiment, this makes it possible to, for example, suppress a reduction in a degree of flatness of the display panel 12.

In the present embodiment, the reinforcement member 47 is bonded to the display panel 12 using, for example, an adhesive. Stress on the display panel 12 is caused due to the adhesive being hardened and shrinking, and the display panel 12 is distorted. This may result in reducing a degree of flatness of the display panel 12.

In other words, the surface of the display panel 12 may exhibit a difference in level in the Z direction, as viewed from the X direction or the Y direction, and it may look like the surface is waving.

When a plurality of adjustment mechanisms 52 is arranged in each side portion of the display panel 12, this results in being able to sufficiently suppress such a difference in level, and to sufficiently suppress a reduction in a degree of flatness of the display panel 12.

The number of adjustment mechanisms 52 is increased to reduce spacing with which the adjustment mechanisms 52 are arranged. This makes it possible to adjust the height of the display panel 12 with a high degree of accuracy, and thus to easily obtain a high degree of flatness. This makes it possible to display a high-quality image.

Conversely, a reduction in the number of adjustment mechanisms 52 enables, for example, simplification of the configuration of the display module 9, a reduction in the number of components, and a reduction in component costs. For example, the number of adjustment mechanisms 52 may be set as appropriate on the basis of such a trade-off relationship.

Each side portion of the peripheral edge of the display panel 12 may be hereinafter referred to as a ridgeline of the display panel 12.

In the present embodiment, the display panel 12 is formed using a material exhibiting a low degree of ridgeline straightness, such as a glass-based material on which a semiconductor process has been performed to obtain a thin film transistor. In other words, a degree of straightness of the side portion of the display panel 12 is easily changed by stress being applied.

Even when the display panel 12 is formed using such a material exhibiting a low degree of ridgeline straightness, the arrangement of a plurality of adjustment mechanisms 52 makes it possible to maintain a high degree of flatness of the display panel 12. This makes it possible to form a circuit for the display panel 12 by a semiconductor process, and thus to reduce manufacturing costs.

Further, even when, for example, a material such as a composite material that exhibits a low degree of ridgeline straightness and easily expands or contracts due to a change in temperature or a change in humidity, is used for the display panel 12, it is possible to suppress a reduction in a degree of flatness of the display panel 12, and thus to display a high-quality image.

Further, in the display apparatus 100 according to the present technology, the height of each display panel 12 is adjusted by the adjustment mechanisms 52 in advance, and the display module 9 is attached to the unit base 10 after the adjustment. The display unit 5 is assembled by this method.

Furthermore, the heights of the four corners of each display unit 5 of a plurality of display units 5 are adjusted to be equal when the display units 5 of the plurality of display units 5 are connected to each other. This makes it possible to adjust the heights of all of the display panels 12 to be equal.

This makes it possible to assemble the display unit 5 in less time. Further, working hours are reduced, and this makes it possible to reduce setup costs such as labor costs related to the setup.

It is assumed that, for example, a method for adjusting heights of the respective display panels 12 to be equal, is used when the display modules 9 are attached to the display unit 5. For example, in this method, there is a need to adjust the heights of the display panels 12 every time a certain display module 9 has a failure and another replacement display module 9 is to be attached.

In the display apparatus according to the present technology, there is no need to adjust the heights of the display panels 12 when the display modules 9 are attached. Consequently, working hours that are necessary when a failure occurs are reduced, and thus a period of time for which the display apparatus 100 is not operated is reduced. Further, service costs such as labor costs related to replacement of the display modules 9 can be reduced.

Stress may be caused on the display panel 12 of the display module 9 due to a change in temperature or humidity. When the display panel 12 is deformed due to the stress, this results in difficulty in displaying a high-quality image.

In the present embodiment, the display panel 12 is sufficiently fixed to the support base 51 by the male screw stud 66 being fitted into the female screw 67 in the adjustment mechanism 52. This makes it possible to prevent the display panel 12 from being deformed.

As described above, the use of the adjustment mechanism 52 using the male screw stud 66 and the female screw 67 makes it possible to prevent the display panel 12 from being deformed.

Moreover, various deformations of each display panel 12, such as inclination and distortion of the display panel 12, and a shift of the display panel 12 in the X direction or the Y direction, are prevented. This results in improving the uniformity of the quality of an image displayed by the display apparatus 100, and thus in displaying a high-quality image.

In the present embodiment, the female screw 67 and the male screw stud 66 are connected to each other through the adjustment-mechanism through hole 63, as illustrated in FIG. 15. In other words, the male screw portion 72 of the male screw stud 66 passes through the adjustment-mechanism through hole 63 to be fitted into the female screw 67.

The size of a diameter of the adjustment-mechanism through hole 63 is set such that the adjustment-mechanism through hole 63 is not brought into contact with the female screw 67 or the male screw stud 66. Thus, the through hole 63 is configured such that there is a space between the adjustment mechanism 52 and the support base 51, and the adjustment mechanism 52 passes through the support base 51 without being brought into contact with the support base 51. In other words, the female screw 67 and the male screw stud 66 are spaced from the support base 51.

This results in preventing the through hole 63 from being brought into contact with the adjustment mechanism 52 upon deformation of the support base 51 and in preventing stress from being transmitted.

The display panel 12 is formed using, for example, glass. Further, the support base 51 is formed using, for example, aluminum. Aluminum exhibits a much higher coefficient of thermal expansion than glass. Thus, when, for example, there is an increase in a temperature of the display apparatus 100, the support base 51 greatly expands relative to the display panel 12.

For example, when no space is provided between the adjustment mechanism 52 and the support base 51, stress is transmitted to the display panel 12 with the expansion of the support base 51. This may result in the display panel 12 being deformed.

In the present embodiment, there is a space between the male screw stud 66 and the support base 51. Thus, the male screw stud 66 and the support base 51 are never brought into contact with each other. Thus, stress is not applied to the male screw stud 66 due to the support base 51. This makes it possible to prevent the display panel 12 and the like from being deformed, and thus to display a high-quality image.

Note that the diameter of the adjustment-mechanism through hole 63 is set sufficiently large such that the support base 51 and the male screw stud 66 are not brought into contact with each other due to expansion of the support base 51. Specifically, how much the support base 51 could expand is calculated in consideration of, for example, the coefficient of thermal expansion of the support base 51 and a possible range of a temperature of the support base, and the size of the diameter is set. Of course, the diameter of the through hole 63 may be set by any method.

Further, in the present embodiment, the positioning pin 45 passes through a positioning-pin through hole 79 to be fitted into the positioning hole 40 arranged in the positioning member 11, as illustrated in FIGS. 10 and 11.

The positioning-pin through hole 79 is configured such that there is a space between the positioning pin 45 and the support base 51. This results in preventing the positioning-pin through hole 79 from being brought into contact with the positioning pin 45 when, for example, the support base 51 is deformed.

This results in preventing stress from being transmitted to the display panel 12 when, for example, the support base 51 is deformed. This makes it possible to prevent the display panel 12 and the like from being deformed, and thus to display a high-quality image.

Note that the diameter of the positioning-pin through hole 79 is set sufficiently large such that the support base 51 and the positioning pin 45 are not brought into contact with each other due to expansion of the support base 51.

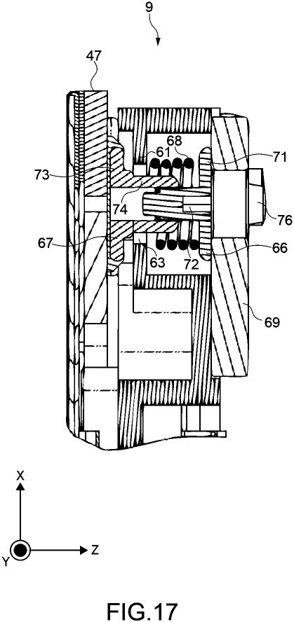

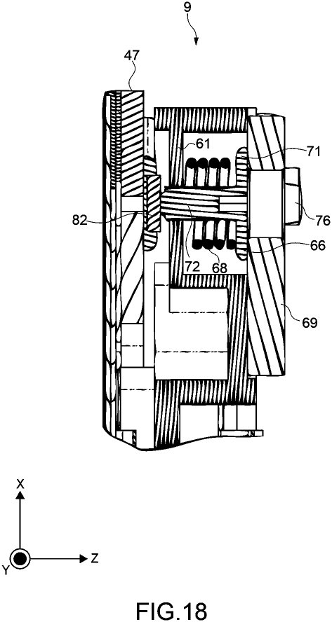

FIGS. 17 and 18 are cross-sectional views each illustrating another example of the configuration of the adjustment mechanism 52.

In the adjustment mechanism 52 illustrated in FIG. 17, the female screw 67 is fixed to a portion, in the reinforcement member 47, that is situated on a side of the display panel 12, and the male screw stud 66 is rotatably connected to the lid member 69.

The head portion 73 of the female screw 67 is fixed to the reinforcement member 47 connected to the display panel 12. The female screw 67 is provided such that the cylindrical portion 74 including a screw hole extends rearwardly.

The head portion 71 of the male screw stud 66 is connected to the front surface of the lid member 69. The male screw stud 66 is provided such that the male screw portion 72 extends forwardly.

An attachment hole is formed in a center portion of the head portion 71 of the male screw stud 66. The rotation member 76 is arranged on the rear side of the lid member 69 to be fixed to the attachment hole of the head portion 71 of the male screw stud 66. This enables the male screw stud 66 and the rotation member 76 to be rotated integrally with each other.

The torsional coil spring 68 is provided between the flat plate portion 61 of the attachment concave portion 60 of the support base 51 and the head portion 71 of the male screw stud 66. The male screw stud 66 is biased by the torsional coil spring 68 toward the lid member 69.

A user rotates the rotation member 76 using, for example, a screwdriver. This makes it possible to adjust a position of the female screw 67 in the Z direction. This results in being able to adjust the height of the display panel 12.

As illustrated in FIG. 17, the size of the through hole 63 of the flat plate portion 61 is set such that there is a space between the through hole 63 and the female screw 67. This makes it possible to prevent stress from being transmitted to the display panel 12 due to, for example, deformation of the support base 51.

In the adjustment mechanism 52 illustrated in FIG. 17, the male screw stud 66 corresponds to an embodiment of a screw that is rotatably attached to a support base. Further, the female screw 67 corresponds to an embodiment of a connection member that is attached to a display panel and connected to the screw.

In the adjustment mechanism 52 illustrated in FIG. 18, a magnet 82 is fixed to a portion, in the reinforcement member 47, that is situated on the side of the display panel 12. Further, the male screw stud 66 is rotatably connected to the lid member 69.

The head portion 71 of the male screw stud 66 is connected to the front surface of the lid member 69. The male screw stud 66 is provided such that the male screw portion 72 extends forwardly.

The male screw stud 66 is connected to the rotation member 76 in a state in which the lid member 69 is situated between the male screw stud 66 and the rotation member 76. This enables the male screw stud 66 and the rotation member 76 to be integrally rotated with respect to the lid member 69.

The male screw stud 66 includes the male screw portion 72 of which at least a tip is a magnetic body. When the magnet 82 and the tip of the male screw portion 72 are brought into contact with each other, the magnet 82 and the tip stick to each other by a magnetic force.

For example, the tip of the male screw portion 72 is made of a magnetic body material such as cobalt or nickel. The entirety of the male screw portion 72 or the entirety of the male screw stud 66 may be made of the magnetic body material.

A screw hole into which the male screw portion 72 of the male screw stud 66 is fitted is formed in the flat plate portion 61 of the attachment concave portion 60 of the support base 51. The rotation of the rotation member 76 enables the tip of the male screw portion 72 to be moved in the Z direction. In other words, the tip of the male screw portion 72 is movably connected to the support base 51 by the male screw portion 72 being rotated.

The torsional coil spring 68 is provided between the flat plate portion 61 of the attachment concave portion 60 of the support base 51 and the head portion 71 of the male screw stud 66. The male screw stud 66 is biased by the torsional coil spring 68 toward the lid member 69. This makes it possible to prevent looseness (backlash) from being caused between the screw hole and the male screw portion 72.

A user rotates the rotation member 76 using, for example, a screwdriver. This makes it possible to adjust a position of the tip of the male screw portion 72 in the Z direction and a position of the magnet 82 controlled by the tip in the Z direction. This results in being able to adjust the height of the display panel 12.

It is assumed that, for example, the support base 51 is deformed due to, for example, a change in temperature. In this case, stress may be transmitted from the screw hole of the flat plate portion 61 to the male screw portion 72. Further, the tip of the male screw portion 72 and the magnet 82 stick to each other by a magnetic force. In other words, the tip of the male screw portion 72 and the magnet 82 are slidably connected to each other.

Thus, each adjustment mechanism 52 can be slid integrally with the reinforcement member 47 to which the magnet 82 is fixed and the display panel 12 according to, for example, deformation of the support base 51. This makes it possible prevent stress from being transmitted to the display panel 12.

In the adjustment mechanism 52 illustrated in FIG. 18, the male screw stud 66 corresponds to an embodiment of a screw of which at least a tip is a magnetic body and of which the tip is movably attached to a support base by the male screw stud 66 being rotated. Further, the magnet 82 corresponds to an embodiment of a connection member that is attached to a display panel and connected to the screw.

### Arrangement of Contact Reference Surface

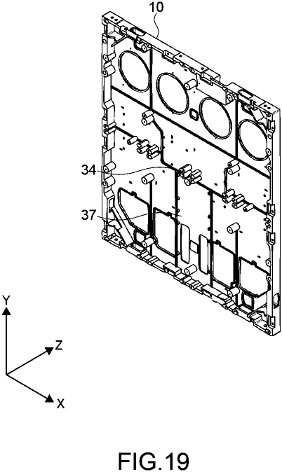

FIG. 19 is a perspective view of the unit base 10 as viewed from the front side.

As illustrated in FIG. 19, the support convex portion 37 including the contact reference surface 34 is arranged in a portion, in the unit base 10, that corresponds to each of four corners of the display panel 12. Thus, the contact reference surface 34 of the unit base 10 is arranged at a position that corresponds to each of the four corners of the display panel 12.

The contact convex portion 46 including the contact reference surface 48 is arranged in a portion, in the support base 51, that corresponds to each of the four corners of the display panel 12 (that is, at each of the four corners of the support base 51). Thus, the contact reference surface 48 of the display module 9 is arranged at each of the four corners of the display panel 12.

The position of each display module 9 with respect to the unit base 10 in the Z direction is determined by the contact reference surface 34 of the unit base 10 and the contact reference surface 48 of the display module 9 being brought into contact with each other.

Here, the entirety of the support convex portion 37 and the contact convex portion 46 in a state in which the contact reference surface 34 and the contact reference surface 48 are in contact with each other is referred to as a Z positioning mechanism 85. Further, a total size (a total height) of the support convex portion 37 and the contact convex portion 46 in the Z direction, that is, a height of the Z positioning mechanism 85 is referred to as a reference height.

The position of each display module 9 with respect to the unit base 10 in the Z direction is determined by the Z positioning mechanism 85. Further, the height of the Z positioning mechanism 85, that is, the reference height corresponds to a height with respect to the unit base 10.

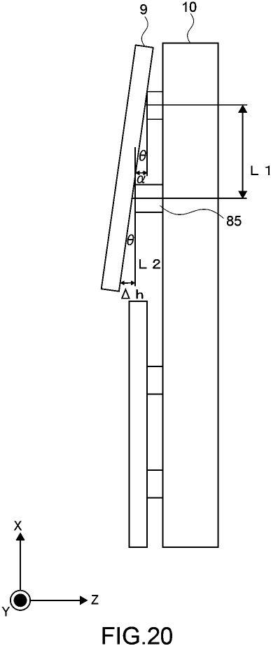

FIG. 20 is a schematic diagram used to describe a position of the Z positioning mechanism 85 with respect to each display module 9.

As described above, the support convex portion 37 and the contact convex portion 46 are precisely processed by machining with respect to respective heights of the support convex portion 37 and the contact convex portion 46. This makes it possible to precisely process the Z positioning mechanism 85 with respect to the reference height of the Z positioning mechanism 85.

Further, a tolerance α may occur for the reference height of the Z positioning mechanism 85 when a plurality of Z positioning mechanisms 85 is arranged for the display panel 12.

It is assumed that, for example, two Z positioning mechanisms 85 are arranged, as illustrated in FIG. 20. Further, it is assumed that a distance between the two Z positioning mechanisms 85 is represented by L1.

In this case, an inclination θ of the display module 9 that occurs due to the tolerance α is represented by a formula indicated below.

$$tan θ = α / \text{L1} \qquad \text{(1)}$$

Further, an amount Δh of shift of a support position of support of an end of the display module 9 is represented by a formula indicated below, the end being situated close to the Z positioning mechanism 85, the support being performed by the Z positioning mechanism 85 (an amount of shift of the support position from an original support position, the support being performed by the Z positioning mechanism 85). Note that L2 represents a distance from the Z positioning mechanism 85 to the end.

$$Δ \text{h} = \text{L2tan} θ \qquad \text{(2)}$$

Note that, in the figure, the distances L1 and L2 are determined, with the center of the Z positioning mechanism 85 in an XY plane being used as a reference.

tanθ of the formula (1) is substituted for the formula (2) to obtain a formula indicated below.

$$Δ \text{h} = α ⋅ \text{L2} / \text{L1} \qquad \text{(3)}$$

This shows that making L1 larger and making L2 smaller is effective in preventing the position of the end of the display module 9 from being shifted in the Z direction due to the tolerance α.

When the Z positioning mechanism 85 is arranged at the peripheral edge 58 of the display panel 12 in consideration of the points described above, this makes it possible to prevent the position of the display surface 53 from being shifted in the Z direction due to the tolerance α. In other words, when the contact convex portion 46 is arranged at the peripheral edge 57 of the support base 51, this makes it possible to prevent the position of the display surface 53 from being shifted in the Z direction.

In the present embodiment, the contact convex portion 46 is arranged at each of the four corners of the support base 51. This makes it possible to sufficiently prevent the position of the display surface 53 from being shifted in the Z direction due to the tolerance α. Further, the Z positioning mechanism 85 is arranged correspondingly to each of the four corners of the display module 9. This makes it possible to stably support the display module 9.

The respective display modules 9 of a plurality of display modules 9 have equal configurations. Thus, the Z positioning mechanism 85 (the contact convex portion 46 and the support convex portion 37) is arranged for each of the four corners of each display module 9. Thus, the support convex portion 37 for a certain display module 9 is provided close to the support convex portion 37 for another display module 9 that is adjacent to the certain display module 9. This indicates that the contact convex portion 46 of a certain display module 9 is provided close to the contact convex portion 46 of another display module 9 that is adjacent to the certain display module 9.

For example, the display unit 5 is viewed from the front in the Z direction. In this case, the Z positioning mechanism 85 (the contact convex portion 46 and the support convex portion 37) arranged at a lower left corner of the display panel 12 situated at a right end in an upper portion is situated close to the Z positioning mechanism 85 (the contact convex portion 46 and the support convex portion 37) arranged at a lower right corner of the second display panel 12 from the right in the upper portion. Further, the Z positioning mechanism 85 (the contact convex portion 46 and the support convex portion 37) arranged at the lower left corner of the display panel 12 situated at the right end in the upper portion is also situated close to the positioning mechanism 85 (the contact convex portion 46 and the support convex portion 37) arranged at an upper left corner of the display panel 12 situated at a right end in a lower portion. Furthermore, the Z positioning mechanism 85 (the contact convex portion 46 and the support convex portion 37) arranged at the lower left corner of the display panel 12 situated at the right end in the upper portion is also situated close to the positioning mechanism 85 (the contact convex portion 46 and the support convex portion 37) arranged at an upper right corner of the second display panel 12 from the right in the lower portion.

As described above, the Z positioning mechanisms 85 (the contact convex portions 46 and the support convex portions 37) of the display modules 9 being adjacent to each other are placed close to each other. This makes it possible to sufficiently prevent the position of the display surface 53 from being shifted in the Z direction due to the tolerance α.

Of course, such a prevention is not limited to when the tolerance α occurs. Even when there is a variation in the reference height of the Z positioning mechanism 85 due to, for example, a degradation over time or a change in temperature, an impact due to such a variation can be sufficiently prevented.

Further, the Z positioning mechanism 85 (the contact convex portion 46 and the support convex portion 37) may be arranged at a position other than the four corners of the peripheral edge 58 of the display panel 12.

The contact convex portion 46 corresponds to an embodiment of at least one contact portion according to the present technology that is arranged at a peripheral edge of a support base and is brought into contact with a support member.

Further, the contact reference surface 48 corresponds to an embodiment of a contact surface according to the present technology that is brought into contact with the support member.

### Connection of Unit Bases

In the present embodiment, the display apparatus 100 includes nine display units 5, as illustrated in FIG. 2. The display units 5 are arranged in a two-dimensional grid, with three display units 5 in the X direction (the right-and-left direction) and three display units 5 in the Y direction (the up-and-down direction).

The respective display units 5 are connected to each other to form the display apparatus 100.

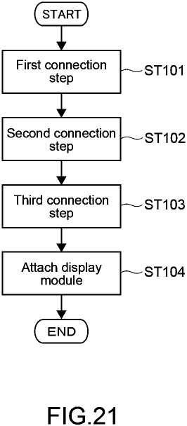

FIG. 21 is a flowchart illustrating an example of a connection method for connecting a plurality of display units 5.

As a first connection step, unit bases 10 of a plurality of unit bases 10 included in a plurality of display units 5 are connected to each other (Step 101). In the present embodiment, the unit bases 10 respectively included in nine display units 5 are connected to each other. In other words, nine unit bases 10 are connected to each other to be arranged in a two-dimensional grid.

As a second connection step, positioning members 11 of a plurality of positioning members 11 included in the plurality of display units 5 are connected to each other (Step 102). In the present embodiment, the positioning members 11 respectively included in the nine display units 5 are connected to each other. In other words, nine positioning members 11 are connected to each other to be arranged in a two-dimensional grid.

As a third connection step, the plurality of connected unit bases 10 and the plurality of connected positioning members 11 are connected to each other (Step 103). In other words, the nine connected positioning members 11 are collectively attached to the nine connected unit bases 10.

Next, the display module 9 is attached (Step 104). In other words, the display modules 9 are attached to the connected nine positioning members 11 and nine unit bases 10. In the present embodiment, eight display modules 9 are attached for one unit base 10. Thus, 72 display modules 9 are attached for the nine unit bases 10.

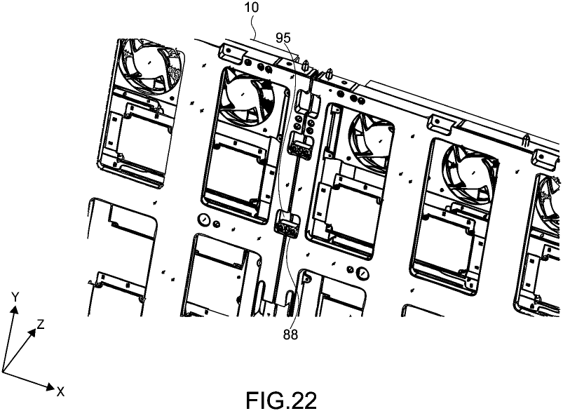

An example of the first connection step corresponding to Step 101 is described with reference to FIGS. 22 to 25.

FIG. 22 is a perspective view of the unit bases 10 as viewed from the upper right on a front side of the unit bases 10.

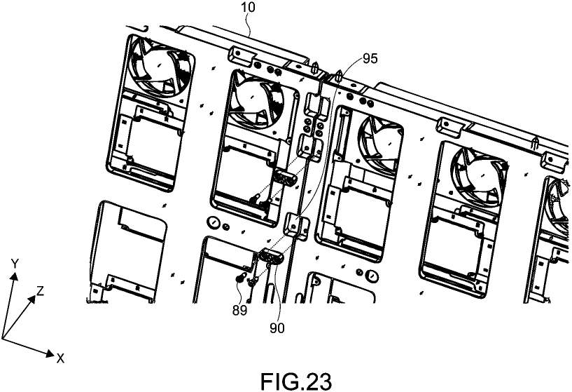

FIG. 23 is a perspective view of the unit bases 10 as viewed from the upper right on the front side of the unit bases 10, and is an exploded perspective view of a unit base coupling plate 88.

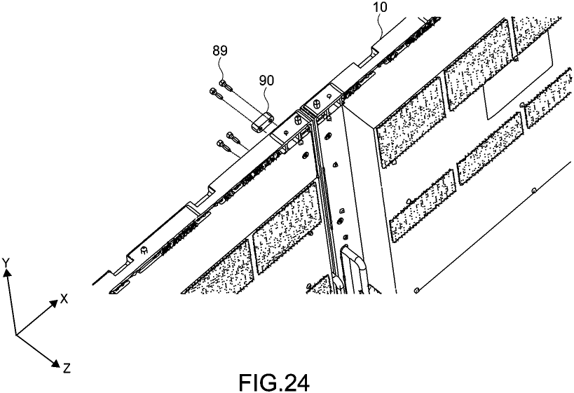

FIG. 24 is a perspective view of the unit bases 10 as viewed from the upper left on a rear side of the unit bases 10, and is an exploded perspective view of the unit base coupling plate 88.

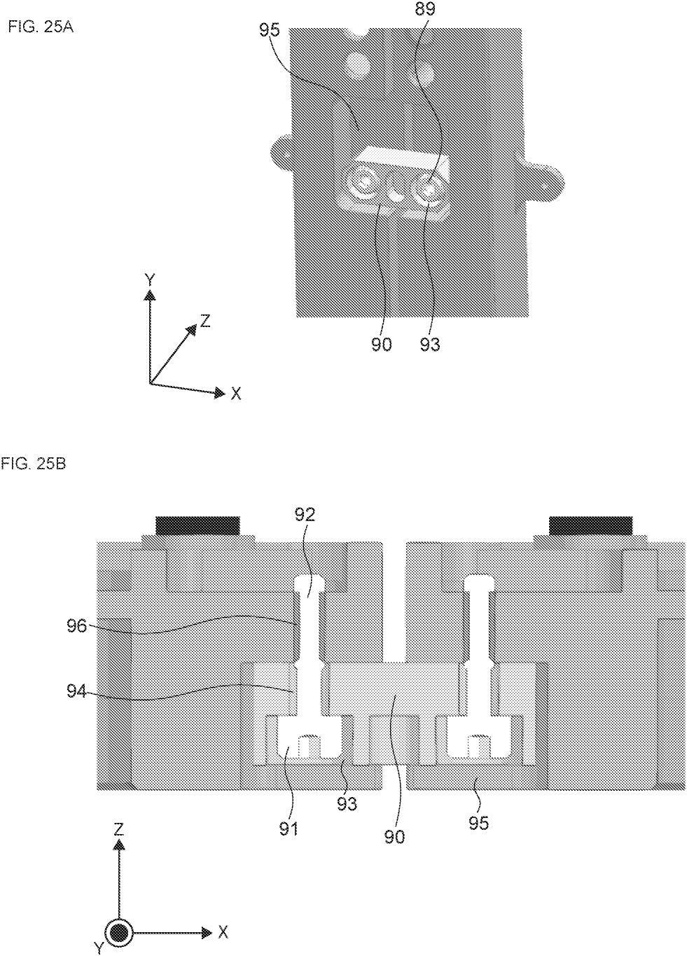

A of FIG. 25 is a perspective view of enlarged portions of the unit bases 10 as viewed from the front side, the enlarged portions being portions to which the unit base coupling plate 88 is attached.

B of FIG. 25 is a cross-sectional view of the unit bases 10 to which the unit base coupling plate 88 is attached, the cross-sectional view being a cross-sectional view when the unit bases 10 are cut along the plane (the XZ-plane) being vertical to the Y direction and including the center of the unit base coupling plate 88.

Note that the unit base 10 illustrated in FIGS. 22 to 25 has a configuration that is different from the configuration of the unit base 10 illustrated in, for example, FIG. 19. FIGS. 22 to 25 each illustrate the unit base 10 to which the positioning member 11 is not connected.

In the present embodiment, the unit base coupling plate 88 is used to connect the unit bases 10.

As illustrated in FIGS. 22 to 24, the unit base coupling plate 88 includes two screws 89 and a coupling portion 90.

B of FIG. 25 is a cross-sectional view of the unit base coupling plate 88 in a state in which the unit base coupling plate 88 is attached.

As illustrated in B of FIG. 25, the screw 89 includes a head portion 91 and a screw portion 92.

The head portion 91 has a shape of a disc. The head portion 91 includes a circular front surface and a circular rear surface.

The screw portion 92 is coupled to the center of the rear surface of the head portion 91 to extend rearwardly. A screw thread is formed in the screw portion 92.

The screw 89 is formed using a metallic material such as iron. Of course, the material of the screw 89 is not limited, and any material may be used.

The coupling portion 90 generally has a shape of a flat plate that is substantially rectangular as viewed from the Z direction, and includes a front surface and a rear surface.

As illustrated in A of FIG. 25, two insertion holes 93 are formed on the front surface of the coupling portion 90. The insertion hole 93 is a hole into which the screw 89 is inserted.

The insertion hole 93 is formed as a concave portion that includes a circular bottom surface. In other words, the insertion hole 93 includes a surface that is circular when the coupling portion is viewed from the front side, the circular surface corresponding to the bottom surface of the concave portion. Further, a through hole 94 that is circular as viewed from the front side is provided to a center portion of the bottom surface of the concave portion. The through hole 94 passes through the coupling portion 90.

As illustrated in B of FIG. 25, the bottom surface of the concave portion of the coupling portion 90 is configured to have a larger diameter than the head portion 91 of the screw 89. Further, setting is performed such that the through hole 94 provided to the bottom surface of the concave portion has a diameter that is larger than a diameter of the screw portion 92 of the screw 89 and is smaller than a diameter of the head portion 91.

Further, setting is performed such that a height of the concave portion of the insertion hole 93, that is, a length of the concave portion in the Z direction is greater than a height of the head portion 91 of the screw 89. Furthermore, setting is performed such that the through hole 94 has a smaller height than the screw portion 92 of the screw.

This makes it possible to insert the screw 89 from the front side of the coupling portion 90, with the head of the screw portion 92 being oriented rearwardly. The screw 89 is inserted such that the head portion 91 of the screw 89 is accommodated in the concave portion of the coupling portion 90 and such that the screw portion 92 passes through the through hole 94.

The coupling portion 90 is formed using a metallic material such as iron. Of course, the material of the coupling portion 90 is not limited, and any material may be used.

Further, each surface of the unit base coupling plate 88 is formed as a processed surface that is precisely processed by machining.

A coupling plate attaching hole 95 is arranged in the unit base 10. The coupling plate attaching hole 95 is a hole used to attach the unit base coupling plate 88.

For example, the coupling plate attaching hole 95 is arranged in a side portion of the unit base 10. In the examples illustrated in FIGS. 22 and 23, two coupling plate attaching holes 95 are arranged in an upper portion of a right side portion of the unit base 10 situated on the left. Further, two coupling plate attaching holes 95 are arranged in an upper portion of a left side portion of the unit base 10 situated on the right. The unit base coupling plate 88 extends into the unit bases on the left and on the right to be attached to a corresponding pair of the adjacent coupling plate attaching holes 95.

Further, in FIGS. 22 and 23, the coupling plate attaching hole 95 is also arranged in an upper side portion of each of the two unit bases 10, although the unit base coupling plate 88 is not attached. The coupling plate attaching hole 95 arranged in the upper side portion is configured such that the unit base 10 is connected to an upper side of each of the two unit bases 10. As described above, the coupling plate attaching hole 95 is arranged in all of the four side portions of a certain unit base 10 such that another unit base 10 is connected on each of upper, lower, right, and left sides of the certain unit base 10.

For example, the coupling plate attaching hole 95 is formed as a concave portion in a side portion of the unit base 10, as illustrated in FIGS. 22 and 23. In the following description, from among surfaces that form the concave portion, the surface vertical to the Z direction may be referred to as a bottom surface of the concave portion, and the surface other than the bottom surface may be referred to as a lateral surface of the concave portion.

In the coupling plate attaching hole 95, the bottom surface and the respective lateral surfaces of the concave portion are each formed as a processed surface that is precisely processed by machining.

As illustrated in FIG. 23, when the unit bases 10 on the right and on the left are arranged side by side, the respective coupling plate attaching holes 95 are adjacently arranged to form a concave portion in the two unit bases 10 arranged side by side, the concave portion including a rectangular bottom surface. In the present embodiment, the unit base coupling plate 88 is inserted into the concave portion formed when the unit bases 10 are arranged side by side. As illustrated in FIG. 22, the unit base coupling plate 88 is inserted with almost no space in the X direction and with a space in the Y direction.

As illustrated in B of FIG. 25, a screw thread 96 is formed in the coupling plate attaching hole 95. The screw thread 96 is formed in order for the screw portion 92 of the screw 89 included in the unit base coupling plate 88 to be fitted into the screw thread 96. The screw thread 96 is formed in a portion, on the bottom surface of the concave portion of the coupling plate attaching hole 95, that is situated further downward in the Y direction than the center of the coupling plate attaching hole 95. Further, the screw thread 96 is formed such that the through hole 94 of the coupling portion 90 and the screw thread 96 substantially coincide in the X direction and in the Y direction.

Of course, the screw thread 96 is formed into a shape that enables the screw portion 92 to be fitted into the screw thread 96.

A of FIG. 25 illustrates the enlarged unit base coupling plate 88 as viewed from the display surface 53 in a state in which the unit base coupling plate 88 is attached to the coupling plate attaching hole 95. As illustrated in A of FIG. 25, the coupling portion 90 of the unit base coupling plate 88 is inserted into a lower portion of the coupling plate attaching hole 95, and two screws 89 are inserted into the coupling portion 90.

As illustrated in B of FIG. 25, the screw portion 92 of the screw 89 is inserted into the through hole 94 of the coupling portion 90 to pass through the coupling portion 90. The screw portion 92 passing through the coupling portion 90 is inserted to be fitted into the screw thread 96 of the extending coupling plate attaching hole 95.

As described above, the unit base coupling plate 88 is fixed to two unit bases 10. This results in the two unit bases 10 being connected to each other. Likewise, the unit bases 10 can be connected in the up-and-down direction. Thus, the unit bases 10 of a plurality of unit bases 10 can be connected in a two-dimensional grid.

Further, the respective surfaces of the unit base coupling plate 88, and the bottom surface and the lateral surfaces of the concave portion of the coupling plate attaching hole 95 are each formed as a processed surface that is precisely processed by machining. This makes it possible to adjust the heights of the respective unit bases 10 with a high degree of accuracy when the unit bases 10 are connected to each other.

The unit base coupling plate 88 corresponds to an embodiment of a first coupling member according to the present technology that couples two adjacent support members of two adjacent display units.

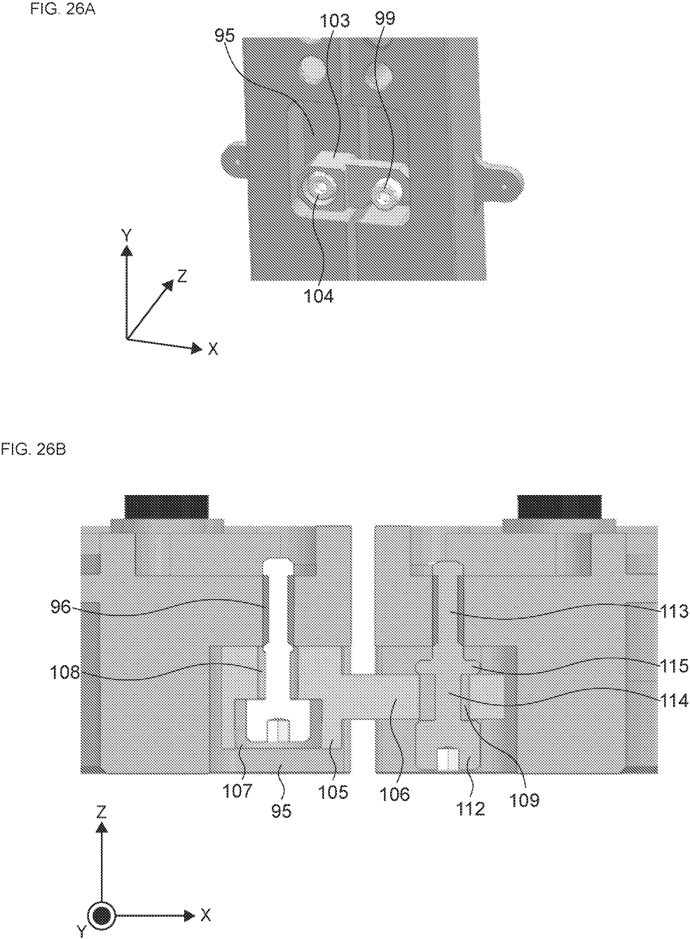

A and B of FIG. 26 illustrate another example of a configuration of the unit base coupling plate 88.

The unit base coupling plate 88 illustrated in A and B of FIG. 26 makes it possible to adjust the heights of the unit bases 10 when the unit bases 10 are connected to each other. This results in being able to sufficiently suppress a difference in height between the respective unit bases 10.

Specifically, as illustrated in A of FIG. 26, the unit base coupling plate 88 includes a height adjustment screw 99. The rotation of the height adjustment screw 99 makes it possible to adjust the heights of the respective unit bases 10.

A of FIG. 26 illustrates the enlarged unit base coupling plate 88 including the height adjustment screw 99, as viewed from the display surface 53, in a state in which the unit base coupling plate 88 is attached to the coupling plate attaching hole 95.

B of FIG. 26 is a cross-sectional view of the unit bases 10 to which the unit base coupling plate 88 including the height adjustment screw 99 is attached, the cross-sectional view being a cross-sectional view when the unit bases 10 are cut along the plane (the XZ-plane) being vertical to the Y direction and including the center of the unit base coupling plate 88.

As illustrated in A of FIG. 26, the unit base coupling plate 88 includes a coupling portion 103, one screw 104, and one height adjustment screw 99.

As illustrated in B of FIG. 26, the coupling portion 103 includes a base portion 105 that has a large thickness, and an adjuster 106 that has a small thickness (the size in the Z direction).

The adjuster 106 has a planar shape, and is coupled to an outer peripheral portion of the base portion 105. The adjuster 106 is coupled to the base portion 105 to extend in a certain direction (the X direction in FIG. 26). Further, the adjuster 106 is coupled to a center portion of the base portion 105 in a thickness direction (the Z direction).

An insertion hole 107 that includes a concave portion is formed in the base portion 105. A through hole 108 is formed in a bottom surface of the insertion hole 107.

A height-adjustment-screw through hole 109 is formed in the adjuster 106. The through hole 108 of the base portion 105 and the height-adjustment-screw through hole 109 of the adjuster 106 are arranged in parallel with a certain direction (the X direction in FIG. 26).

The height adjustment screw 99 includes a head portion 112, a screw portion 113, and a body portion 114. The body portion 114 is formed between the head portion 112 and the screw portion 113. The body portion 114 includes a disc-shaped flange 115 that is formed at a boundary of the screw portion 113 and the body portion 114.

The height adjustment screw 99 is formed using a metallic material such as iron. Of course, the material of the height adjustment screw 99 is not limited, and any material may be used.

As illustrated in B of FIG. 26, setting is performed such that a portion, of the body portion 114, that is other than the flange 115 has a diameter that is substantially equal to a diameter of the screw portion 113. Further, setting is performed such that the height-adjustment-screw through hole 109 has a larger diameter than the portion, of the body portion 114, that is other than the flange 115.

Further, the diameters of the flange 115 and the head portion 112 are set substantially equal to each other and larger than the diameter of the height-adjustment-screw through hole 109. Furthermore, setting is performed such that the height-adjustment-screw through hole 109 has a length substantially equal to a distance between the head portion 112 and the flange 115.

In the present embodiment, a portion from the head portion 112 to the flange 115 that is included in the body portion 114 of the height adjustment screw 99 is inserted into the height-adjustment-screw through hole 109, as illustrated in B of FIG. 26. The height adjustment screw 99 is attached to be rotatable with respect to the adjuster 106.

The screw thread 96 corresponding to the screw thread illustrated in, for example, B of FIG. 25 is formed in the coupling plate attaching hole 95 of the unit base 10. A screw portion of the screw 104 attached to the base portion 105 is fitted into the screw thread 96 of the coupling plate attaching hole 95 of a certain unit base 10, and the screw portion 113 of the height adjustment screw 99 is fitted into the screw thread 96 of the coupling plate attaching hole 95 of another unit base 10 that is connected to the certain unit base 10.

When the height adjustment screw 99 is rotated, this makes it possible to change a height of the unit base 10 on the right with respect to the unit base 10 on the left. This makes it possible to adjust the heights of the respective unit bases 10. In other words, when a height of the unit base 10 is adjusted using the height adjustment screw 99, this makes it possible to adjust the heights of the respective unit bases 10 to be equal.

Further, the rotation of the height adjustment screw 99 makes it possible to make a minor adjustment of heights. This results in accurately adjusting the heights of the respective unit bases 10.

### Connection of Positioning Members

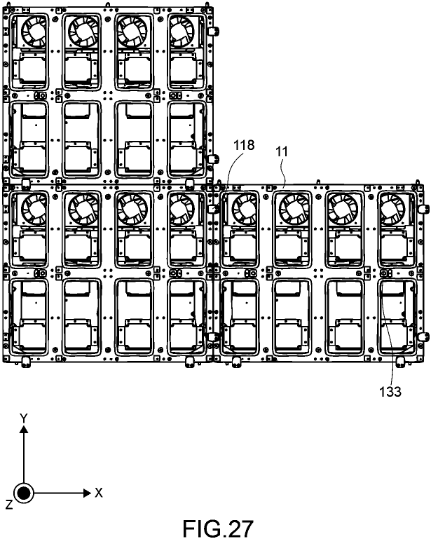

An example of the second connection step corresponding to Step 102 is described with reference to FIGS. 27 to 32.

FIG. 27 illustrates a plurality of connected positioning members 11 as viewed from a front side of the plurality of connected positioning members 11. FIG. 27 illustrates a state in which a plurality of connected positioning members 11 is connected to a plurality of connected unit base 10. In other words, the figure illustrates a state after the third connection step. Here, the connection of the positioning members 11 of the plurality of positioning members 11 is described.

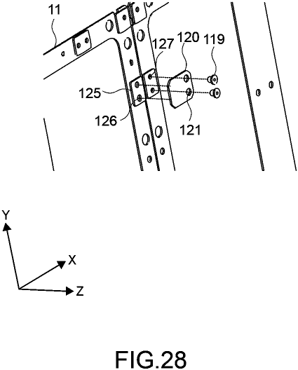

FIG. 28 is a perspective view of a plurality of positioning members 11 as viewed from the upper left on the front side of the plurality of positioning members 11, and is an exploded perspective view of a positioning member coupling plate 118.

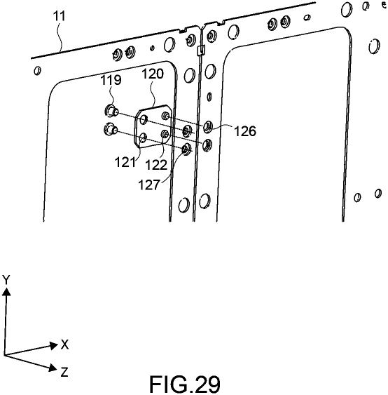

FIG. 29 is a perspective view of the plurality of positioning members 11 as viewed from the upper left on a rear side of the plurality of positioning members 11, and is an exploded perspective view of the positioning member coupling plate 118.

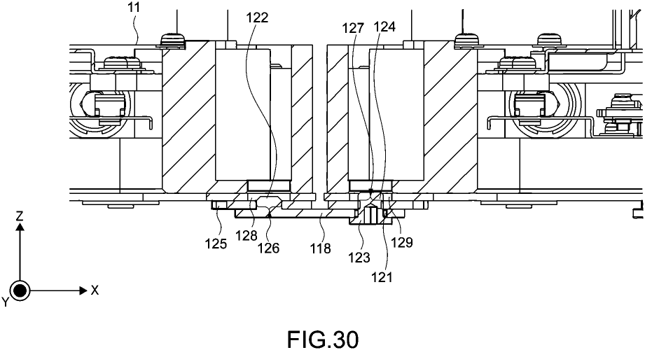

FIG. 30 is a cross-sectional view of the plurality of positioning members 11 to which the positioning member coupling plate 118 is attached, the cross-sectional view being a cross-sectional view when the plurality of positioning members 11 is cut along the plane (the XZ-plane) being vertical to the Y direction and including the center of the positioning member coupling plate 118.

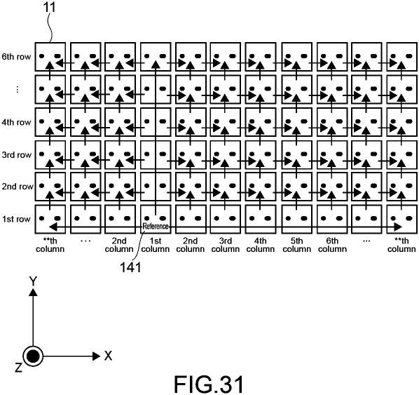

FIG. 31 is a schematic diagram used to describe the connection of the positioning members 11 using an assembling fixture.

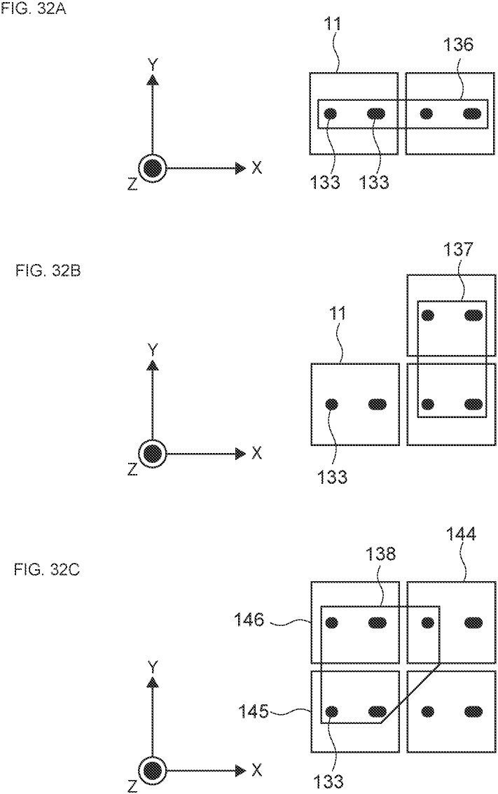

FIG. 32 schematically illustrates the order of connecting the positioning members 11.

In the present embodiment, the positioning member coupling plate 118 is used in order to connect the positioning members 11.

FIG. 27 illustrates three positioning members 11 that are coupled in the X direction and in the Y direction.

In the example illustrated in FIG. 27, on the right of a certain positioning member 11 illustrated on the lower left, another positioning member 11 is coupled to the certain positioning member 11. On an upper side of the certain positioning member 11, yet another positioning member 11 is coupled to the certain positioning member 11.

With respect to the two positioning members 11 coupled in the right-and-left direction, two positioning member coupling plates 118 each extend into a right side portion of the positioning member 11 situated on the right and a left side portion of the positioning member 11 situated on the left to be connected to the right side portion of the positioning member 11 situated on the right and the left side portion of the positioning member 11 situated on the left. One of the two positioning member coupling plates 118 is connected to be situated in a portion further upward in the Y direction than the center of each side portion. Further, another of the two positioning member coupling plates 118 is connected to be situated in a portion further downward in the Y direction than the center of each side portion.

As described above, the positioning members 11 on the right and on the left are connected by the respective positioning members 11 being fixed by the two positioning member coupling plates 118.

Likewise, the positioning members 11 are connected by two positioning member coupling plates 118 in the up-and-down direction.

FIG. 28 is a perspective view of a portion situated near a coupling portion of coupling two positioning members 11 when the two positioning members 11 are coupled in the right-and-left direction. Specifically, with respect to the positioning members 11 coupled in the right-and-left direction,

FIG. 28 is a perspective view primarily illustrating a portion that includes an upper portion of a right side portion of the positioning member 11 situated on the left as viewed from the display surface and an upper portion of a left side portion of the positioning member 11 situated on the right as viewed from the display surface.

In other words, FIG. 28 illustrates a portion that corresponds to a portion around the positioning member coupling plate 118 situated in upper portions of the positioning members 11 being coupled in the right-and-left direction and illustrated in FIG. 27.

Note that FIG. 28 is also an exploded perspective view of the positioning member coupling plate 118.

FIG. 29 is an exploded perspective view when FIG. 28 is viewed from the rear side.

As illustrated in FIGS. 28 and 29, the positioning member coupling plate 118 includes two screws 119 and a coupling portion 120.

The coupling portion 120 has a flat-plate shape. The coupling portion 120 is substantially rectangular as viewed from the Z direction. Two through holes 121 and two dowels 122 are arranged in the coupling portion 120.

The through hole 121 is a hole that is circular as viewed from the Z direction. The two through holes 121 are both arranged in a right portion of the coupling portion 120 as viewed from a front side of the coupling portion 120.

Setting is performed that the through hole 121 has a larger diameter than the screw 119. In other words, the screw 119 can pass through the through hole 121.

The dowel 122 is arranged as a cylindrical convex portion on a rear surface of the coupling portion 120.

As illustrated in FIG. 29, the two dowels 122 are both arranged in a right portion of a rear surface of the coupling portion 120 as viewed from a rear side of the coupling portion 120. In other words, when the coupling portion 120 is viewed from the front side, the two dowels 122 are arranged in a left portion of the back of the coupling portion 120.

The coupling portion 120 is formed using a metallic material such as iron. Of course, the material of the coupling portion 120 is not limited, any material may be used.

The two screws 119 each includes a head portion 123 and a screw portion 124.

In the present embodiment, a sheet metal 125 is connected to positioning member 11. The positioning member coupling plate 118 is connected at substantially the same location as the sheet metal 125 in the X direction and in the Y direction.

The sheet metal 125 has a flat-plate shape. The sheet metal 125 is substantially rectangular as viewed from the Z direction. For example, the sheet metal 125 is connected to an upper portion of a right side portion of the positioning member 11 situated on the left. Further, the sheet metal 125 is also connected to an upper portion of a left side portion of the positioning member 11 situated on the right.

The sheet metal 125 is formed using a metallic material such as aluminum. Of course, the material of the sheet metal 125 is not limited, and any material may be used. Further, the sheet metal 125 may be arranged in the positioning member 11 by being formed integrally with the positioning member 11.

As illustrated in FIG. 28, the sheet metal 125 connected to each positioning member 11 includes two fitting holes. The sheet metal 125 connected to the positioning member 11 situated on the left includes two dowel fitting holes 126. Further, the sheet metal 125 connected to the positioning member 11 situated on the right includes two screw fitting holes 127.

The dowel fitting hole 126 is a hole into which the dowel 122 is fitted. The sheet metal 125 connected to the positioning member 11 situated on the left vertically includes two dowel fitting holes 126.

A diameter of the dowel fitting hole 126 is set substantially equal to a diameter of the dowel 122. This results in the dowel 122 being fitted into the dowel fitting hole 126 with almost no space in the X direction and in the Y direction.

The screw fitting hole 127 is a hole into which the screw 119 of the positioning member coupling plate 118 is fitted. As in the case of the dowel fitting hole 126, two screw fitting holes 127 are respectively arranged in upper and lower portions of the sheet metal 125 connected to the positioning member 11 situated on the right.

A screw thread is arranged in the screw fitting hole 127 such that the screw 119 of the positioning member coupling plate 118 can be fitted into the screw thread.

Further, as illustrated in FIG. 30, two dowel through holes 128 and two screw through holes 129 are arranged in the positioning member 11.

The dowel through hole 128 is arranged in the positioning member 11 situated on the left such that the dowel through hole 128 and the dowel fitting hole 126 arranged in the sheet metal 125 substantially coincide in the X direction and in the Y direction. Further, the screw through hole 129 is arranged in the positioning member 11 situated on the right such that the screw through hole 129 and the screw fitting hole 127 arranged in the sheet metal 125 substantially coincide in the X direction and in the Y direction.

The dowel through hole 128 is a hole through which the dowel 122 passes. The screw through hole 129 is a hole through which the screw 119 passes.

The positioning member coupling plate 118 is connected to the positioning member 11 to which the sheet metal 125 is connected. Specifically, first, the dowel 122 arranged in the coupling portion 120 of the positioning member coupling plate 118 is inserted to be fitted into the dowel fitting hole 126 arranged in the sheet metal 125. The dowel 122 passes through the sheet metal 125, and a tip of the dowel 122 is inserted into the dowel through hole 128 of the positioning member 11.

Next, the screw 119 is inserted into the through hole 121 of the coupling portion 120 of the positioning member coupling plate 118. The screw 119 passes through the coupling portion 120, and the screw portion 124 is fitted into the screw fitting hole 127 arranged in the sheet metal 125. The screw 119 passes through the sheet metal 125, and a tip of the screw 119 is inserted into the screw through hole 129 of the positioning member 11.

The positioning member coupling plate 118 is connected to the positioning member 11, as described above. The positioning member coupling plate 118 is stably connected to the positioning member 11 by the dowel 122 and the screw 119 being fitted into the positioning member 11.

Note that an assembling fixture is used when the positioning members 11 are connected to each other using the positioning member coupling plate 118.

A function and the like of the assembling fixture will be described later.

In the third connection step corresponding to Step 103, a plurality of positioning members 11 being coupled to each other as described above is connected to a plurality of coupled unit bases 10. Further, the display modules 9 are attached in Step 104 to form a large-sized display apparatus 100.

Eight display modules 9 and one positioning member 11 can be integrally slid with respect to one unit base 10 in one display unit 5. Likewise, the entirety of the display modules 9 and the entirety of the positioning members 11, which are included in the display apparatus 100, can be integrally slid with respect to the entirety of the unit bases 10 included in the display apparatus 100.

When the unit bases 10 of a plurality of unit bases 10 are connected to each other, the plurality of unit bases 10 may be deformed due to a weight of the plurality of unit bases 10. In such a case, a plurality of positioning members 11 is also relatively slipped to be slid with respect to the plurality of unit bases 10. This makes it possible to prevent a plurality of positioning members 11 from being affected by stress caused in response to a plurality of unit bases 10 being deformed.

Thus, for example, the number of longitudinally coupled display units 5 can be greatly increased. This makes it possible to obtain the display apparatus 100 having a large screen.

Further, it becomes possible to prevent the display panel 12 from being affected by stress. This makes it possible to use glass exhibiting a low breaking stress as a material of the display panel 12. This results in improving the mass productivity of the display panel 12.

Note that it is also possible to prevent a plurality of positioning members 11 from being affected by stress when a plurality of unit bases 10 is deformed due to a change in temperature or humidity.

Further, a relative positional relationship between the display panels 12 is not affected even when a plurality of unit bases 10 is deformed. In other words, the display modules 9 are attached such that there is a space between the display panels 12 in the X direction and in the Y direction, but there is a space between the display panels 12 under all circumstances. An appropriate space is secured between the display panels 12 at all times, and this makes it possible to remove the display panel 12 with certainty.

Further, the position of a plurality of display modules 9 is determined with respect to a plurality of positioning members 11 in the X direction and in the Y direction. In other words, there is no need to adjust the position of the display module 9 when the display module 9 is placed. This results in reducing the time necessary to place the display module 9. Further, this results in improving the accuracy in the position of the display module 9.

The positioning member coupling plate 118 corresponds to an embodiment of a second coupling member according to the present technology that couples two adjacent positioning members that are respectively included in two adjacent display units.

The positioning member coupling plate 118 may include no dowel 122, and the positioning member coupling plate 118 may be connected to the positioning member 11 only using the fitting of the screw 119. When, for example, the positioning members 11 are coupled in the right-and-left direction using such a positioning member coupling plate 118, the positioning member coupling plate 118 includes two screws 119. One of the two screws 119 is fitted into the screw fitting hole 127 of the sheet metal 125 arranged in the positioning member 11 situated on the left. Further, another of the two screws 119 is fitted into the screw fitting hole 127 of the sheet metal 125 arranged in the positioning member 11 situated on the right. This results in connecting the respective positioning members 11 and the positioning member coupling plate 118.

Further, the positioning members 11 may be directly connected to each other without using the positioning member coupling plate 118. For example, the positioning members 11 may be connected by bonding using an adhesive. Moreover, the method for connecting the positioning members 11 is not limited.

### Method for Connecting Positioning Member Using Assembling Fixture

When the positioning members 11 are connected to each other using the positioning member coupling plate 118, an assembling fixture is used. A method for connecting the positioning members 11 using an assembling fixture, and a procedure of the connection are described.

In the present embodiment, a fixture hole 133 is arranged in the positioning member 11. The fixture hole 133 is a hole into which a pin member of the assembling fixture is fitted.

The assembling fixture is used to fix the positioning members 11 when the positioning members 11 are connected to each other. A specific shape of the assembling fixture is not limited, and any assembling fixture that is designed to make it possible to connect the positioning members 11 may be adopted.

In the present embodiment, the assembling fixture includes the pin member.

The fixture hole 133 is arranged in the positioning member 11.

As illustrated in FIG. 27, two fixture holes 133 are arranged for one positioning member 11.

One of the two fixture holes 133 is arranged in a portion, in the middle rib 17 of the positioning member 11, that is situated close to a leftmost partition rib 18. Another of the two fixture holes 133 is arranged in a portion, in the middle rib 17 of the positioning member 11, that is situated close to a rightmost partition rib 18.

The fixture hole 133 is a hole that is circular as viewed from the Z direction. In the present embodiment, the fixture hole 133 is a hole through the positioning member 11. However, the fixture hole 133 may be a concave portion that is circular as viewed from the Z direction.

A diameter of the fixture hole 133 is set substantially equal to a diameter of the pin member of the assembling fixture. In other words, the pin member is fitted into the fixture hole 133 with almost no space in the X direction and in the Y direction.

In the present embodiment, an assembling fixture, from among three different types of assembling fixtures, is used depending on the direction of coupling the positioning members 11. For example, a right-and-left fixture 136 is used when the positioning members 11 are coupled to each other in the right-and-left direction.

Further, an up-and-down fixture 137 is used when the positioning members 11 are coupled to each other in the up-and-down direction.

Note that when the positioning members 11 are coupled to each other in the right-and-left direction and when another positioning member 11 is already coupled to a lower side of the positioning member 11 to be newly coupled, there is a need to perform coupling in the right-and-left direction and in the up-and-down direction at the same time. A combination-use fixture 138 is used in such a case.

A of FIG. 32 schematically illustrates the positioning members 11 coupled using the right-and-left fixture 136.

A of FIG. 32 illustrates the positioning members 11 arranged in the right-and-left direction, the fixture holes 133, and the right-and-left fixture 136. Two squares illustrated in A of FIG. 32 schematically represent the positioning members 11. Further, a rectangle schematically represents the right-and-left fixture 136. Four points schematically represent the fixture holes 133 each arranged in a corresponding one of the positioning members 11.

The right-and-left fixture 136 includes four pin members. When the positioning members 11 are coupled to each other in the right-and-left direction, the four pin members are respectively fitted into the fixture holes 133 of which two are arranged in each positioning member 11. This results in the respective positioning members 11 being fixed to each other.

The positioning member coupling plate 118 is connected to the positioning members 11 in a state of being fixed to each other. This results in the positioning members 11 being coupled to each other in the right-and-left direction.

B of FIG. 32 schematically illustrates the positioning members 11 coupled using the up-and-down fixture 137.

B of FIG. 32 schematically illustrates the case in which, after the positioning members 11 are coupled in the right-and-left direction, as in the case of A of FIG. 32, the positioning member 11 is further coupled on an upper side of the positioning member 11 being coupled in the right-and-left direction and situated on the right.

A rectangle illustrated in B of FIG. 32 schematically represents the up-and-down fixture 137. As in the case of the coupling using the right-and-left fixture 136, the pin member is fitted into the fixture hole 133, and the positioning members 11 are connected to each other in the up-and-down direction.

C of FIG. 32 schematically illustrates the positioning members 11 coupled to each other using the combination-use fixture 138.

C of FIG. 32 schematically illustrates the case in which, after three positioning members 11 are coupled, as in the case of B of FIG. 32, a positioning member 146 is coupled on a left side of a positioning member 144 that is situated on the upper right and on an upper side of a positioning member 145 that is situated on the lower left.

A pentagon illustrated in C of FIG. 32 schematically represents the combination-use fixture 138. When coupling is performed using the combination-use fixture 138, the pin member is fitted into the fixture hole 133 on the left in the positioning member 144 situated on the upper right. Further, the pin members are respectively fitted into the fixture holes 133 of which two are arranged in each of the positioning member 146 situated on the upper left and the positioning member 145 situated on the lower left. This results in the positioning member 146 being coupled.

The use of the assembling fixture results in the positioning member coupling plate 118 being connected in a state in which the positioning members 11 are fixed to each other in position. This makes it possible to accurately connect a plurality of positioning members 11. For example, it is possible to prevent each of the positioning members 11 connected in a two-dimensional grid from being shifted in the X direction and in the Y direction.

This also results in preventing each of the display modules 9 attached to the positioning member 11 from being shifted in the X direction and in the Y direction. This makes it possible to display a high-quality image.

FIG. 31 schematically illustrates the order of connecting the positioning members 11.

In the present embodiment, the positioning members 11 are connected in the order indicated by arrows illustrated in FIG. 31.

Note that the respective positioning members 11 are assembled in a state of being arranged in a plane, that is, in a state of being arranged such that the display surface 53 is vertical to a direction of gravity.

In the following description, a set of the positioning members 11 being coupled in a two-dimensional grid and arranged in the up-and-down direction may be referred to as a column, and a set of the positioning members 11 being coupled in a two-dimensional grid and arranged in the right-and-left direction may be referred to as a row, as illustrated in FIG. 31.

First, one positioning member 11 is arranged. Thereafter, the first arranged positioning member 11 is referred to as a reference-position determining member 141.

In FIG. 31, from among the positioning members 11 arranged in a two-dimensional grid, the reference-position determining member 141 is the fourth positioning member 11 from the left in a lowermost line.

In the following description, a column in which the reference-position determining member 141 is arranged is referred to as a first column, a column on the right of the first column is referred to as a second column, and a column on the right of the second column is referred to as a third column, as illustrated in FIG. 31. A number of a column on a right side of the first column is denoted as indicated above. Further, a column on the left of the first column is referred to as a second column, and a column on the left of the second column is referred to as a third column, as illustrated in FIG. 31. Likewise, a number of a column on a left side of the first column is denoted as indicated above. With respect to the same column number used on the right side and the left side, the orientation may be indicated as necessary, such as a second column on the right and a second column on the left.

Next, at least two positioning members 11 are connected in the right-and-left direction using the right-and-left fixture 136. In other words, at least one positioning member 11 is connected to the reference-position determining member 141 in the right-and-left direction.

The number of positioning members 11 connected is determined depending on, for example, the size of the display apparatus 100. When the display apparatus 100 includes nine display units 5, as in the case of the display apparatus 100 illustrated in FIG. 2, three positioning members 11 are arranged in the right-and-left direction. In other words, two positioning members 11 are connected to the reference-position determining member 141.

Further, when, for example, the display apparatus 100 having a large screen is desired to be obtained, a large number of positioning members 11 are connected in the right-and-left direction. Moreover, the number of positioning members 11 connected in the right-and-left direction is not limited.

Next, at least two positioning members 11 are connected in the up-and-down direction using the up-and-down fixture 137.

In the present embodiment, at least one positioning member 11 is connected to the reference-position determining member 141 in an upper direction.

The number of positioning members 11 connected in the up-and-down direction is not limited.

Next, the positioning members 11 are connected to each other using the combination-use fixture 138.

In the present embodiment, the positioning member 11 is connected at a position that is situated in a second row in a second column on the right. Specifically, one positioning member 11 is simultaneously connected on an upper side of the positioning member 11 situated in a first row in a second column on the right and on a right side of the positioning member 11 in a second row in the first column.

Next, for example, the positioning member 11 is connected at a position that is situated in the second row in a third column on the right.

Next, for example, the positioning member 11 is connected at a position that is situated in a third row in the second column on the right.

As described above, the positioning member 11 is repeatedly connected such that one positioning member 11 is simultaneously connected to already connected two positioning members 11.

Further, for example, the positioning member 11 may be connected at the position situated in the third row in the second column on the right after the positioning member 11 is connected at the position situated in the second row in the second column on the right. The order of connecting the positioning members 11 using the combination-use fixture 138 is not limited, and a method of connection in any order may be adopted, where the method includes repeatedly coupling the positioning members 11 on upper sides of two already connected positioning members 11 and in the right-and-left direction.

In the examples illustrated in FIGS. 31 and 32, the right-and-left direction corresponds to an embodiment of a first direction according to the present technology. The up-and-down direction corresponds to an embodiment of a second direction according to the present technology, the second direction being orthogonal to the first direction.

The right-and-left fixture 136 corresponds to an embodiment of a first fixture according to the present technology that fixes two positioning members such that the two positioning members are adjacently arranged in parallel with the first direction.

The up-and-down fixture 137 corresponds to an embodiment of a second fixture according to the present technology that fixes two positioning members such that the two positioning members are adjacently arranged in parallel with the second direction.

The combination-use fixture 138 corresponds to an embodiment of a third fixture according to the present technology that fixes a second positioning member to a first positioning member such that the first and second positioning members are adjacently arranged in parallel with the first direction, and fixes a third positioning member to the first positioning member such that the first and third positioning members are adjacently arranged in parallel with the second direction.

In the example illustrated in C of FIG. 32, the positioning member 146 corresponds to the first positioning member, and the positioning member 144 corresponds to the second positioning member. Further, the positioning member 145 corresponds to the third positioning member.

As described above, the display apparatus 100 according to the present embodiment includes at least one display module 9. The display module includes the adjustment mechanism 52, and can adjust a relative distance of the display panel 12 to the support base 51. This makes it possible to display a high-quality image.

Further, in the display apparatus 100 according to the present embodiment, the positioning member 11 determining a position of at least one display module 9 with respect to the unit base 10 is slidably connected to the unit base 10. This makes it possible to display a high-quality image.

The respective configurations of the display apparatus, the display unit, the positioning member, the unit base, the display module, the display panel, the support base, and the adjustment mechanism; the assembly of the display apparatus; the flows of connecting the respective members; and the like described with reference to the respective figures are merely embodiments, and any modifications may be made thereto without departing from the spirit of the present technology. In other words, for example, any other configurations or algorithms for purpose of practicing the present technology may be adopted.

When wording such as “substantially” or “about” is used in the present disclosure, such wording is merely used to facilitate the understanding of the description, and whether the wording such as “substantially” or “about” is used has no particular significance.

In other words, in the present disclosure, expressions, such as “center”, “middle”, “uniform”, “equal”, “similar”, “orthogonal”, “parallel”, “symmetric”, “extend”, “axial direction”, “columnar”, “cylindrical”, “ring-shaped”, and “annular” that define, for example, a shape, a size, a positional relationship, and a state respectively include, in concept, expressions such as “substantially the center/substantial center”, “substantially the middle/substantially middle”, “substantially uniform”, “substantially equal”, “substantially similar”, “substantially orthogonal”, “substantially parallel”, “substantially symmetric”, “substantially extend”, “substantially axial direction”, “substantially columnar”, “substantially cylindrical”, “substantially ring-shaped”, and “substantially annular”.

For example, the expressions such as “center”, “middle”, “uniform″, “equal”, “similar”, “orthogonal”, “parallel”, “symmetric”, “extend”, “axial direction”, “columnar”, “cylindrical”, “ring-shaped”, and “annular” also respectively include states within specified ranges (such as a range of +/-10%), with expressions such as “exactly the center/exact center”, “exactly the middle/exactly middle”, “exactly uniform”, “exactly equal”, “exactly similar”, “completely orthogonal”, “completely parallel”, “completely symmetric”, “completely extend”, “fully axial direction”, “perfectly columnar”, “perfectly cylindrical”, “perfectly ring-shaped”, and “perfectly annular” being respectively used as references.

Thus, an expression that does not include the wording such as “substantially” or “about” can also include, in concept, an expression including the wording such as “substantially” or “about”. Conversely, a state expressed using the expression including the wording such as “substantially” or “about” may include a state of “exactly/exact”, “completely”, “fully”, or “perfectly”.

In the present disclosure, an expression using “-er than” such as “being larger than A” and “being smaller than A” comprehensively includes, in concept, an expression that includes “being equal to A” and an expression that does not include “being equal to A”. For example, “being larger than A” is not limited to the expression that does not include “being equal to A”, and also includes “being equal to or greater than A”. Further, “being smaller than A” is not limited to “being less than A”, and also includes “being equal to or less than A”.

When the present technology is carried out, it is sufficient if a specific setting or the like is adopted as appropriate from expressions included in “being larger than A” and expressions included in “being smaller than A”, in order to provide the effects described above.

At least two of the features of the present technology described above can also be combined. In other words, the various features described in the respective embodiments may be combined discretionarily regardless of the embodiments. Further, the various effects described above are not limitative but are merely illustrative, and other effects may be provided.

Note that the present technology may also take the following configurations.

A display apparatus, including
at least one display module that includes
   a display panel that is capable of displaying an image,
   a support base that supports the display panel, and
   an adjustment mechanism that is connected to the display panel and connected to the support base, the adjustment mechanism being capable of adjusting a relative distance of the display panel to the support base.

The display apparatus according to (1), in which
the display panel includes a display surface on which the image is displayed, and
the adjustment mechanism is capable of adjusting the distance in a direction that is vertical to the display surface.

The display apparatus according to (2), in which

the adjustment mechanism moves the display panel relative to the support base in parallel with the direction vertical to the display surface.

The display apparatus according to (3), in which

the adjustment mechanism includes a screw that is attached to the support base, and a connection member that is attached to the display panel and connected to the screw, the adjustment mechanism adjusting the distance by the screw being rotated relative to the connection member.

The display apparatus according to (4), in which
the screw is rotatably attached to the support base, and
the adjustment mechanism adjusts the distance by the rotation of the screw.

The display apparatus according to (5), in which
the screw is a female screw, and
the connection member is a male screw that is fitted into the screw.

The display apparatus according to (5), in which
the screw is a male screw, and
the connection member is a female screw into which the screw is fitted.

The display apparatus according to (5), in which
the screw is a male screw of which at least a tip is a magnetic body,
the tip of the screw is movably attached to the support base by the rotation of the screw, and
the connection member is a magnet that is brought into contact with the tip.

The display apparatus according to any one of (5) to (7), in which
the adjustment mechanism includes a fixation member that rotatably holds the screw and is fixed to the support base, and
the screw and the connection member are spaced from the support base.

The display apparatus according to (9), in which
the support base includes a flat plate portion that is arranged parallel to the display surface and in which a through hole is formed,
the screw and the connection member are connected to each other through the through hole, and
the through hole has a diameter of a size such that the through hole is not brought into contact with the screw or the connection member.

The display apparatus according to (10), in which

the adjustment mechanism includes a biasing member that is arranged between the fixation member and the flat plate portion, the biasing member biasing the screw toward the fixation member.

The display apparatus according to any one of (1) to (11), in which
the display panel is rectangular as viewed from a direction that is vertical to the display surface, and
the adjustment mechanisms are respectively arranged at positions of a plurality of positions on a peripheral edge of the display panel.

The display apparatus according to (12), in which

the adjustment mechanism is arranged at each of four corners of the display panel.

The display apparatus according to (12) or (13), in which

each of the plurality of positions is situated in at least one portion between two ends of each of four side portions of the display panel.

The display apparatus according to any one of (1) to (14), in which
the at least one display module is a plurality of display modules, and
the display apparatus further includes a support member that supports the plurality of display modules.

The display apparatus according to (15), in which
the display panel is rectangular as viewed from a direction that is vertical to the display surface,
the support base has a shape that is equal to the shape of the display panel as viewed from the direction vertical to the display surface, and
each of the plurality of display modules includes at least one contact portion that is arranged at a peripheral edge of the support base and is brought into contact with the support member.

The display apparatus according to (16), in which
the at least one contact portion includes a contact surface that is brought into contact with the support member, and
the adjustment mechanism adjusts the distance in the direction vertical to the display surface such that a distance between the contact surface and the display surface exhibits a specified value.

A display module, including:
a display panel that is capable of displaying an image;
a support base that supports the display panel; and
an adjustment mechanism that is connected to the display panel and connected to the support base, the adjustment mechanism being capable of adjusting a relative distance of the display panel to the support base.

Reference Signs List

| | |
|---|---|
| 5 | display unit |
| 9 | display module |
| 10 | unit base |
| 11 | positioning member |
| 12 | display panel |
| 13 | back surface portion |
| 22 | stepped screw |
| 23 | through hole |
| 24 | attachment hole |
| 33 | magnet |
| 34, 48 | contact reference surface |
| 37 | support convex portion |
| 44 | magnetic body member |
| 46 | contact convex portion |
| 51 | support base |
| 52 | adjustment mechanism |
| 53 | display surface |
| 57 | peripheral edge of display panel |
| 58 | peripheral edge of support base |
| 60 | attachment concave portion |
| 61 | flat plate portion |
| 66 | male screw stud |
| 67 | female screw |
| 69 | lid member |
| 88 | unit base coupling plate |
| 118 | positioning member coupling plate |
| 136 | right-and-left fixture |
| 137 | up-and-down fixture |
| 138 | combination-use fixture |

1. A display apparatus, comprising
at least one display module that includes
a display panel that is capable of displaying an image,
a support base that supports the display panel, and
an adjustment mechanism that is connected to the display panel and connected to the support base, the adjustment mechanism being capable of adjusting a relative distance of the display panel to the support base.

2. The display apparatus according to claim 1, wherein
the display panel includes a display surface on which the image is displayed, and
the adjustment mechanism is capable of adjusting the distance in a direction that is vertical to the display surface.

3. The display apparatus according to claim 2, wherein
the adjustment mechanism moves the display panel relative to the support base in parallel with the direction vertical to the display surface.

4. The display apparatus according to claim 3, wherein
the adjustment mechanism includes a screw that is attached to the support base, and a connection member that is attached to the display panel and connected to the screw, the adjustment mechanism adjusting the distance by the screw being rotated relative to the connection member.

5. The display apparatus according to claim 4, wherein
the screw is rotatably attached to the support base, and
the adjustment mechanism adjusts the distance by the rotation of the screw.

6. The display apparatus according to claim 5, wherein
the screw is a female screw, and
the connection member is a male screw that is fitted into the screw.

7. The display apparatus according to claim 5, wherein
the screw is a male screw, and
the connection member is a female screw into which the screw is fitted.

8. The display apparatus according to claim 5, wherein
the screw is a male screw of which at least a tip is a magnetic body,
the tip of the screw is movably attached to the support base by the rotation of the screw, and
the connection member is a magnet that is brought into contact with the tip.

9. The display apparatus according to claim 5, wherein
the adjustment mechanism includes a fixation member that rotatably holds the screw and is fixed to the support base, and
the screw and the connection member are spaced from the support base.

10. The display apparatus according to claim 9, wherein
the support base includes a flat plate portion that is arranged parallel to the display surface and in which a through hole is formed,
the screw and the connection member are connected to each other through the through hole, and
the through hole has a diameter of a size such that the through hole is not brought into contact with the screw or the connection member.

11. The display apparatus according to claim 10, wherein
the adjustment mechanism includes a biasing member that is arranged between the fixation member and the flat plate portion, the biasing member biasing the screw toward the fixation member.

12. The display apparatus according to claim 1, wherein
the display panel is rectangular as viewed from a direction that is vertical to the display surface, and
the adjustment mechanisms are respectively arranged at positions of a plurality of positions on a peripheral edge of the display panel.

13. The display apparatus according to claim 12, wherein
the adjustment mechanism is arranged at each of four corners of the display panel.

14. The display apparatus according to claim 12, wherein
each of the plurality of positions is situated in at least one portion between two ends of each of four side portions of the display panel.

15. The display apparatus according to claim 1, wherein
the at least one display module is a plurality of display modules, and
the display apparatus further comprises a support member that supports the plurality of display modules.

16. The display apparatus according to claim 15, wherein
the display panel is rectangular as viewed from a direction that is vertical to the display surface,
the support base has a shape that is equal to the shape of the display panel as viewed from the direction vertical to the display surface, and
each of the plurality of display modules includes at least one contact portion that is arranged at a peripheral edge of the support base and is brought into contact with the support member.

17. The display apparatus according to claim 16, wherein
the at least one contact portion includes a contact surface that is brought into contact with the support member, and
the adjustment mechanism adjusts the distance in the direction vertical to the display surface such that a distance between the contact surface and the display surface exhibits a specified value.

18. A display module, comprising:
a display panel that is capable of displaying an image;
a support base that supports the display panel; and
an adjustment mechanism that is connected to the display panel and connected to the support base, the adjustment mechanism being capable of adjusting a relative distance of the display panel to the support base.
